(19) United States
(12) Patent Application Publication
(10) Pub. No.: US 2024/0237525 A1
(43) Pub. Date: Jul. 11, 2024

(54) Organic Light Emitting Diode and Organic Light Emitting Device Including the Same

(71) Applicant: LG Display Co., Ltd., Seoul (KR)

(72) Inventors: Jong-Uk Kim, Paju-si (KR); Gi-Hwan Lim, Paju-si (KR); In-Ae Shin, Paju-si (KR); Jun-Yun Kim, Paju-si (KR)

(21) Appl. No.: 18/504,973

(22) Filed: Nov. 8, 2023

(30) Foreign Application Priority Data
Dec. 26, 2022 (KR) 10-2022-0184528

(51) Int. Cl. H10K 85/60; C09K 11/06

(52) U.S. Cl. CPC H10K 85/6572; C09K 11/06; H10K 85/6574; H10K 85/658; H10K 50/12

(57) ABSTRACT

The present disclosure relates to an organic light emitting diode comprising a first electrode; a second electrode facing the first electrode; and a first emitting part including a first red emitting material layer and positioned between the first and second electrode, the first red emitting material layer including a first delayed fluorescent compound, a second delayed fluorescent compound and a first fluorescent compound, wherein the first delayed fluorescent compound is represented by Formula 1, the second delayed fluorescent compound is represented by Formula 3, and the first fluorescent compound is represented by Formula 5.

### CROSS-REFERENCE TO RELATED APPLICATIONS

The present application claims the benefit of Republic of Korea Patent Application No. 10-2022-0184528 filed in the Republic of Korea on Dec. 26, 2022, which is hereby incorporated by reference in its entirety.

### FIELD OF TECHNOLOGY

The present disclosure relates to an organic light emitting diode (OLED), and more specifically, to an OLED having advantages in a driving voltage, an emitting efficiency and a lifespan and an organic light emitting device including the OLED.

### BACKGROUND

As requests for a flat panel display device having a small occupied area have been increased, an organic light emitting display device including an OLED has been the subject of recent research and development.

The OLED emits light by injecting electrons from a cathode as an electron injection electrode and holes from an anode as a hole injection electrode into an emitting material layer (EML), combining the electrons with the holes, generating an exciton, and transforming the exciton from an excited state to a ground state. A flexible substrate, for example, a plastic substrate, can be used as a base substrate where elements are formed. In addition, the organic light emitting display device can be operated at a voltage (e.g., 10V or below) lower than a voltage required to operate other display devices. Moreover, the organic light emitting display device has advantages in the power consumption and the color sense.

The OLED includes a first electrode as an anode over a substrate, a second electrode, which is spaced apart from and faces the first electrode, and an organic emitting layer therebetween, and the organic emitting layer includes a dopant (an emitter).

A fluorescent compound among dopant compounds has a narrow full width at half maximum (FWHM) to provide a high color purity. However, the fluorescent compound has low emitting efficiency.

### SUMMARY

The present disclosure is directed to an OLED and an organic light emitting device including the OLED that substantially obviate one or more of the problems associated with the limitations and disadvantages of the related conventional art.

Additional features and advantages of the present disclosure are set forth in the description which follows, and will be apparent from the description, or evident by practice of the present disclosure. The objectives and other advantages of the present disclosure are realized and attained by the features described herein as well as in the appended drawings.

To achieve these and other advantages in accordance with the purpose of the embodiments of the present disclosure, as described herein, an aspect of the present disclosure is an organic light emitting diode comprising a first electrode; a second electrode facing the first electrode; and a first emitting part including a first red emitting material layer and positioned between the first and second electrode, the first red emitting material layer including a first delayed fluorescent compound, a second delayed fluorescent compound, and a first fluorescent compound, wherein the first delayed fluorescent compound is represented by Formula 1:

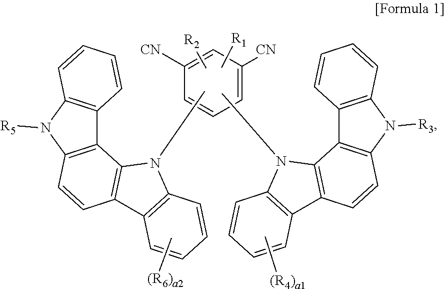

wherein in the Formula 1, each of a1 and a2 is independently an integer of 0 to 4, each of R₁ and R₂ is independently selected from the group consisting of a substituted or unsubstituted C6 to C30 aryl group and a substituted or unsubstituted C3 to C30 heteroaryl group, each of R₃ and R₅ is independently selected from the group consisting of hydrogen, deuterium, a substituted or unsubstituted C1 to C10 alkyl group, a substituted or unsubstituted C6 to C30 aryl group and a substituted or unsubstituted C3 to C30 heteroaryl group, and each of R₄ and R₆ is independently selected from the group consisting of a substituted or unsubstituted C1 to C10 alkyl group, a substituted or unsubstituted C1 to C10 alkoxy group, a substituted or unsubstituted C3 to C30 cycloalkyl group, a substituted or unsubstituted C6 to C30 aryl group and a substituted or unsubstituted C3 to C30 heteroaryl group, wherein the second delayed fluorescent compound is represented by Formula 3:

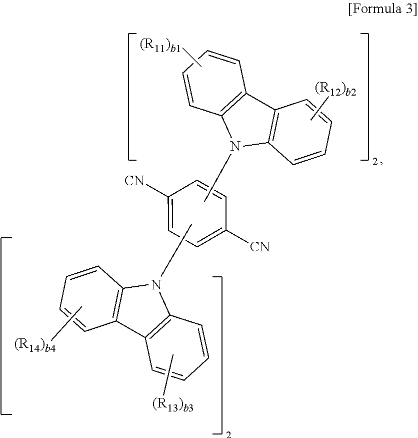

wherein in the Formula 3, each of b1 to b4 is independently an integer of 0 to 4, and each of R₁₁ to R₁₄ is independently selected from the group consisting of a substituted or unsubstituted C1 to C10 alkyl group, a substituted or unsubstituted C1 to C10 alkoxy group, a substituted or unsubstituted C3 to C30 cycloalkyl group, a substituted or unsubstituted C6 to C30 aryl group and a substituted or unsubstituted C3 to C30 heteroaryl group, wherein the first fluorescent compound is represented by Formula 5:

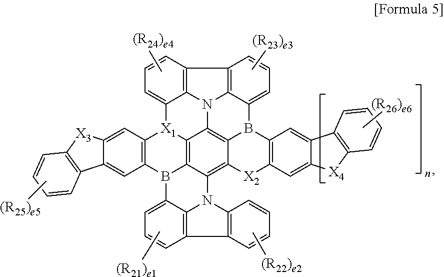

wherein in the Formula 5, each of e1 and e3 is independently an integer of 0 to 3, each of e2, e4, e5 and e6 is independently an integer of 0 to 4, and n is 0 or 1, each of X₁, X₂, X₃, and X₄ is independently selected from the group consisting of O, S, Se, and Te, and each of R₂₁ to R₂₆ is independently selected from the group consisting of deuterium, a substituted or unsubstituted C1 to C10 alkyl group, a substituted or unsubstituted C1 to C10 alkoxy group, a substituted or unsubstituted C3 to C30 cycloalkyl group, a substituted or unsubstituted C6 to C30 aryl group and a substituted or unsubstituted C3 to C30 heteroaryl group.

Another aspect of the present disclosure is an organic light emitting device comprising a substrate; the above organic light emitting diode over the substrate; and an encapsulation layer covering the organic light emitting diode.

It is to be understood that both the foregoing general description and the following detailed description are exemplary and explanatory and are intended to further explain the present disclosure as claimed.

### BRIEF DESCRIPTION OF THE DRAWINGS

The accompanying drawings, which are included to provide a further understanding of the present disclosure and are incorporated in and constitute a part of this specification, illustrate embodiments of the present disclosure and together with the description serve to explain the principles of the present disclosure.

FIG. 1 is a schematic circuit diagram illustrating an organic light emitting display device of the present disclosure.

FIG. 2 is a schematic cross-sectional view illustrating an organic light emitting display device according to a first embodiment of the present disclosure.

FIG. 3 is a schematic cross-sectional view illustrating an OLED according to a second embodiment of the present disclosure.

FIG. 4 is a view illustrating an energy relation of compounds in an EML of an OLED of the present disclosure.

FIG. 5 is a schematic cross-sectional view illustrating an OLED according to a third embodiment of the present disclosure.

FIG. 6 is a schematic cross-sectional view illustrating an organic light emitting display device according to a fourth embodiment of the present disclosure.

FIG. 7 is a schematic cross-sectional view illustrating an OLED according to a fifth embodiment of the present disclosure.

FIG. 8 is a schematic cross-sectional view illustrating an OLED according to a sixth embodiment of the present disclosure.

FIG. 9 is a schematic cross-sectional view illustrating an OLED according to a seventh embodiment of the present disclosure.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When ‘including’, ‘having’, ‘consisting’, and the like are used in this specification, other parts may be added unless ‘only’ is used. When a component is expressed in the singular, cases including the plural are included unless specific statement is described.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure may be partially or overall coupled to or combined with each other, and may be variously inter-operated with each other and driven technically as those skilled in the art can sufficiently understand. The aspects of the present disclosure may be carried out independently from each other, or may be carried out together in co-dependent relationship.

Reference will now be made in detail to some of the examples and preferred embodiments, which are illustrated in the accompanying drawings.

In an OLED of the present disclosure, an emitting material layer includes a first delayed fluorescent compound, a second delayed fluorescent compound, and a fluorescent compound, and an organic light emitting device includes the OLED. The organic light emitting device may be an organic light emitting display device or an organic lightening device. As an example, an organic light emitting display device, which is a display device including the OLED of the present disclosure, will be mainly described.

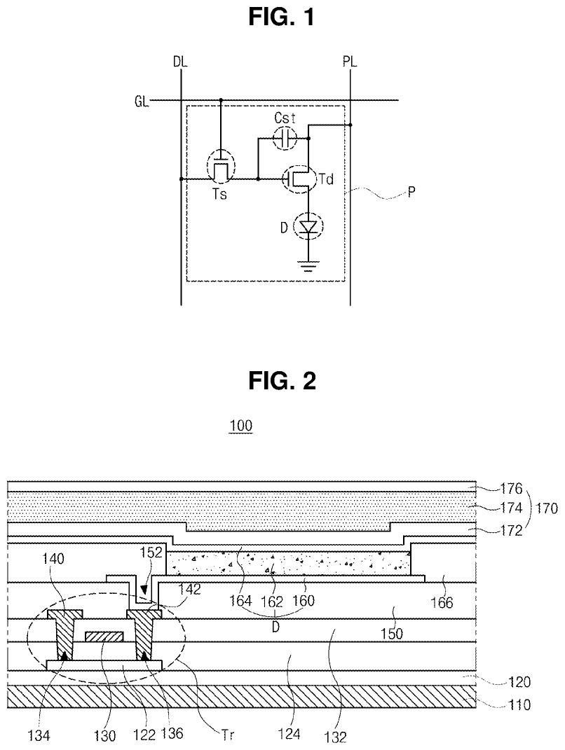

FIG. 1 is a schematic circuit diagram illustrating an organic light emitting display device of the present disclosure.

As illustrated in FIG. 1, a gate line GL and a data line DL, which cross each other to define a pixel region P, and a power line PL are formed in an organic light display device. A switching thin film transistor (TFT) Ts, a driving thin film transistor (TFT) Td, a storage capacitor Cst and an OLED D are formed in the pixel region P. The pixel region P may include a red pixel region, a green pixel region and a blue pixel region.

The switching thin film transistor Ts is connected to the gate line GL and the data line DL, and the driving thin film transistor Td and the storage capacitor Cst are connected between the switching thin film transistor Ts and the power line PL. The OLED D is connected to the driving thin film transistor Td.

When the switching thin film transistor Ts is turned on by the gate signal applied through the gate line GL, the data signal applied through the data line DL is applied to a gate electrode of the driving thin film transistor Td and one electrode of the storage capacitor Cst through the switching thin film transistor Ts.

The driving thin film transistor Td is turned on by the data signal applied into the gate electrode so that a current proportional to the data signal is supplied from the power line PL to the OLED D through the driving thin film transistor Td. The OLED D emits light having a luminance proportional to the current flowing through the driving thin film transistor Td.

In this case, the storage capacitor Cst is charged with a voltage proportional to the data signal so that the voltage of the gate electrode in the driving thin film transistor Td is kept constant during one frame.

Therefore, the organic light emitting display device can display a desired image.

FIG. 2 is a schematic cross-sectional view illustrating an organic light emitting display device according to a first embodiment of the present disclosure.

As illustrated in FIG. 2, the organic light emitting display device 100 includes a substrate 110, a TFT Tr and an OLED D disposed on a planarization layer and connected to the TFT Tr.

The substrate 110 may be a glass substrate or a flexible substrate. For example, the flexible substrate may be a polyimide (PI) substrate, a polyethersulfone (PES) substrate, a polyethylenenaphthalate (PEN) substrate, a polyethylene terephthalate (PET) substrate or a polycarbonate (PC) substrate.

A buffer layer 120 is formed on the substrate, and the TFT Tr is formed on the buffer layer 120. The buffer layer 120 may be omitted.

A semiconductor layer 122 is formed on the buffer layer 120. The semiconductor layer 122 may include an oxide semiconductor material or polycrystalline silicon. When the semiconductor layer 122 includes the oxide semiconductor material, a light-shielding pattern (not shown) may be formed under the semiconductor layer 122. The light to the semiconductor layer 122 is shielded or blocked by the light-shielding pattern such that thermal degradation of the semiconductor layer 122 can be prevented. On the other hand, when the semiconductor layer 122 includes polycrystalline silicon, impurities may be doped into both sides of the semiconductor layer 122.

A gate insulating layer 124 is formed on the semiconductor layer 122. The gate insulating layer 124 may be formed of an inorganic insulating material such as silicon oxide (SiOx) or silicon nitride (SiNx).

A gate electrode 130, which is formed of a conductive material, e.g., metal, is formed on the gate insulating layer 124 to correspond to a center of the semiconductor layer 122. In FIG. 2, the gate insulating layer 124 is formed on an entire surface of the substrate 110. Alternatively, the gate insulating layer 124 may be patterned to have the same shape as the gate electrode 130.

An interlayer insulating layer 132, which is formed of an insulating material, is formed on the gate electrode 130. The interlayer insulating layer 132 may be formed of an inorganic insulating material, e.g., silicon oxide or silicon nitride, or an organic insulating material, e.g., benzocyclobutene or photo-acryl.

The interlayer insulating layer 132 includes first and second contact holes 134 and 136 exposing both sides of the semiconductor layer 122. The first and second contact holes 134 and 136 are positioned at both sides of the gate electrode 130 to be spaced apart from the gate electrode 130. The first and second contact holes 134 and 136 are formed through the gate insulating layer 124. Alternatively, when the gate insulating layer 124 is patterned to have the same shape as the gate electrode 130, the first and second contact holes 134 and 136 is formed only through the interlayer insulating layer 132.

A source electrode 140 and a drain electrode 142, which are formed of a conductive material, e.g., metal, are formed on the interlayer insulating layer 132. The source electrode 140 and the drain electrode 142 are spaced apart from each other with respect to the gate electrode 130 and respectively contact both sides of the semiconductor layer 122 through the first and second contact holes 134 and 136.

The semiconductor layer 122, the gate electrode 130, the source electrode 140 and the drain electrode 142 constitute the TFT Tr. The TFT Tr serves as a driving element. Namely, the TFT Tr may correspond to the driving TFT Td (of FIG. 1).

In the TFT Tr, the gate electrode 130, the source electrode 140, and the drain electrode 142 are positioned over the semiconductor layer 122. Namely, the TFT Tr has a coplanar structure. Alternatively, in the TFT Tr, the gate electrode may be positioned under the semiconductor layer, and the source and drain electrodes may be positioned over the semiconductor layer such that the TFT Tr may have an inverted staggered structure. In this instance, the semiconductor layer may include amorphous silicon.

Although not shown, the gate line and the data line cross each other to define the pixel region, and the switching TFT is formed to be connected to the gate and data lines. The switching TFT is connected to the TFT Tr as the driving element. In addition, the power line, which may be formed to be parallel to and spaced apart from one of the gate and data lines, and the storage capacitor for maintaining the voltage of the gate electrode of the TFT Tr in one frame may be further formed.

A planarization layer 150 is formed on the source and drain electrodes 140 and 142 and over an entire surface of the substrate 110. The planarization layer 150 has a flat top surface and includes a drain contact hole 152 exposing the drain electrode 142 of the TFT Tr.

The OLED D is disposed on the planarization layer 150 and includes a first electrode 160, which is connected to the drain electrode 142 of the TFT Tr, an organic emitting layer 162 on the first electrode 160 and a second electrode 164 on the organic emitting layer 162. The OLED D is disposed at each of the red, green and blue pixel regions and emits red light, green light and blue light in the red, green and blue pixel regions, respectively.

The first electrode 160 is separately formed in each pixel region. The first electrode 160 may be an anode and may be formed of a conductive material having a relatively high work function. For example, the first electrode 160 may be formed of a conductive material having a relatively high work function, e.g., a transparent conductive oxide (TCO), for example, the first electrode 160 may include at least one of indium-tin-oxide (ITO), indium-zinc-oxide (IZO), indium-tin-zinc oxide (ITZO), tin oxide (SnO), zinc oxide (ZnO), indium-copper-oxide (ICO) and aluminum-zinc-oxide (Al:ZnO, AZO).

When the organic light emitting display device 100 is operated in a bottom-emission type, the first electrode 160 may have a single-layered structure formed of the transparent conductive oxide. Alternatively, when the organic light emitting display device 100 is operated in a top-emission type, the first electrode 160 may further include a reflective layer to have a double-layered structure or a triple-layered structure. For example, the reflective layer may include silver (Ag) or aluminum-palladium-copper alloy (APC). In the top-emission type organic light emitting display device 100, the first electrode 160 may have a double-layered structure of Ag/ITO or APC/ITO or a triple-layered structure of ITO/Ag/ITO or ITO/APC/ITO.

A bank layer 166 is formed on the planarization layer 150 to cover an edge of the first electrode 160. Namely, the bank layer 166 is positioned at a boundary of the pixel region and exposes a center of the first electrode 160 in the pixel region.

An organic emitting layer 162 is formed on the first electrode 160. The organic emitting layer 162 may have a single-layered structure of an emitting material layer (EML). Alternatively, the organic emitting layer 162 may further include at least one of a hole injection layer (HIL), a hole transport layer (HTL), an electron blocking layer (EBL), a hole blocking layer (HBL), an electron transport layer (ETL) and an electron injection layer (EIL) to have a multi-layered structure. In addition, two or more EMLs may be disposed to be spaced from each other so that the OLED D may have a tandem structure.

In the red pixel region, the organic emitting layer 162 of the OLED D includes a first delayed fluorescent compound, a second delayed fluorescent compound, and a fluorescent compound so that the emitting efficiency and the lifespan of the OLED D and the organic light emitting display device 100 are significantly improved.

The second electrode 164 is formed over the substrate 110 where the organic emitting layer 162 is formed. The second electrode 164 covers an entire surface of the display area and may be formed of a conductive material having a relatively low work function to serve as a cathode. For example, the second electrode 164 may be formed of a material having high reflectance, such as aluminum (Al), magnesium (Mg), calcium (Ca), silver (Ag), their alloys or their combinations. In the top-emission type organic light emitting display device 100, the second electrode 164 may have a thin profile (small thickness) to provide a light transmittance property (or a semi-transmittance property).

An encapsulation layer (or encapsulation film) 170 is formed on the second electrode 164 to prevent penetration of moisture into the OLED D. The encapsulation film 170 includes a first inorganic insulating layer 172, an organic insulating layer 174 and a second inorganic insulating layer 176 sequentially stacked, but it is not limited thereto. The encapsulation film 170 may be omitted.

In the bottom-emission type organic light emitting display device 100, a metal plate may be disposed on the encapsulation layer 170.

The organic light emitting display device 100 may include a color filter layer corresponding to the red, green and blue pixel regions. The color filter layer may include red, green and blue color filters respectively corresponding to the red, green and blue pixel regions. The organic light emitting display device 100 with the color filter layer may have improved color purity.

In the bottom-emission type organic light emitting display device 100, the color filter layer may be disposed between the OLED D and the substrate 110, e.g., between the interlayer insulating layer 132 and the planarization layer 150. In the top-emission type organic light emitting display device 100, the color filter layer may be disposed over the OLED D, e.g., on or over the second electrode 164 or the encapsulation layer 170.

The organic light emitting display device 100 may further include a polarization plate for reducing an ambient light reflection. For example, the polarization plate may be a circular polarization plate. In the bottom-emission type organic light emitting display device 100, the polarization plate may be disposed under the substrate 110. In the top-emission type organic light emitting display device 100, the polarization plate may be disposed on or over the encapsulation film 170.

In addition, in the top-emission type organic light emitting display device 100, a cover window may be attached to the encapsulation film 170 or the polarization plate. In this instance, the substrate 110 and the cover window have a flexible property such that a flexible organic light emitting display device may be provided.

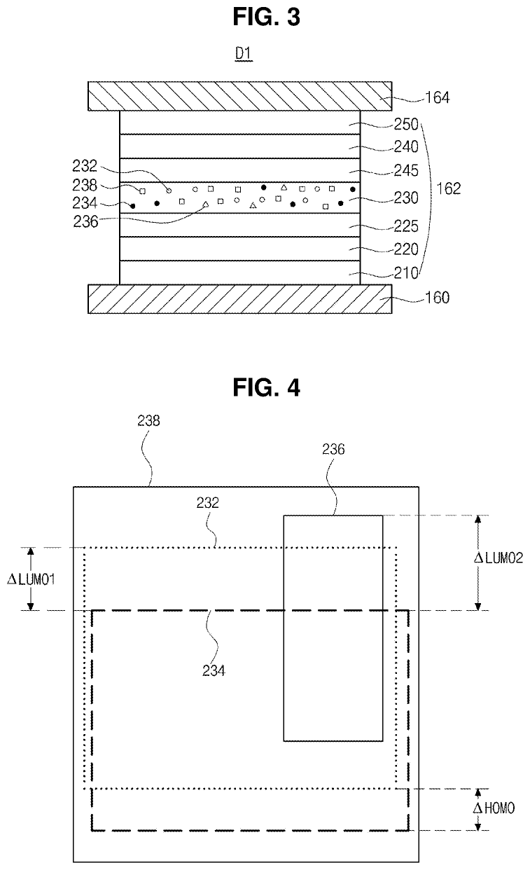

FIG. 3 is a schematic cross-sectional view illustrating an OLED according to a second embodiment of the present disclosure.

As illustrated in FIG. 3, the OLED D1 includes the first and second electrodes 160 and 164, which face each other, and the organic emitting layer 162 therebetween, and the organic emitting layer 162 includes a red EML 230.

The organic light emitting display device 100 (of FIG. 2) includes red, green, and blue pixel regions. In addition, the organic light emitting display device 100 may further include a white pixel region. The OLED D1 may be positioned in the red pixel region.

The organic light emitting layer 162 in the green pixel region includes a green EML, and the organic light emitting layer 162 in the blue pixel region includes a blue EML.

The first electrode 160 is an anode, and the second electrode 164 is a cathode. One of the first and second electrodes 160 and 164 is a reflective electrode, and the other one of the first and second electrodes 160 and 164 is a transparent (semitransparent) electrode.

For example, the first electrode 160 may include a transparent conductive material layer formed of ITO or IZO, and the second electrode 164 may include one of Al, Mg, Ag, AlMg, and MgAg.

The organic emitting layer 162 may further include at least one of the HTL 220 under the red EML 230 and the ETL 240 on or over the red EML 230. Namely, the HTL 220 is disposed between the red EML 230 and the first electrode 160, and the ETL 240 is disposed between the red EML 230 and the second electrode 164.

In addition, the organic emitting layer 162 may further include at least one of the HIL 210 under the HTL 220 and the EIL 250 on the ETL 240.

Moreover, the organic emitting layer 162 may further include at least one of the EBL 225 between the HTL 220 and the red EML 230 and the HBL 245 between the red EML 230 and the ETL 240.

The HIL 210 may include a hole injection material being at least one compound selected from the group consisting of 4,4′,4″-tris(3-methylphenylamino)triphenylamine (MTDATA), 4,4′,4″-tris(N,N-diphenyl-amino)triphenylamine (NATA), 4,4′,4″-tris(N-(naphthalene-1-yl)-N-phenyl-amino)triphenylamine (IT-NATA), 4,4′,4″-tris(N-(naphthalene-2-yl)-N-phenyl-amino)triphenylamine (2T-NATA), copper phthalocyanine (CuPc), tris(4-carbazoyl-9-yl-phenyl)amine (TCTA), N,N′-diphenyl-N,N′-bis(1-naphthyl)-1,1′-biphenyl-4,4″-diamine (NPB or NPD), 1,4,5,8,9,11-hexaazatriphenylenehexacarbonitrile (HAT-CN), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, and N,N′-diphenyl-N,N′-di[4-(N,N-diphenyl-amino)phenyl]benzidine (NPNPB), but it is not limited thereto. The HIL 210 may have a thickness of 5 to 15 nm.

The HTL 220 may include a hole transporting material being at least one compound selected from the group consisting of N,N′-diphenyl-N,N′-bis(3-methylphenyl)-1,1′-biphenyl-4,4′-diamine (TPD), NPB (or NPD), 4,4′-bis(N-carbazolyl)-1,1′-biphenyl (CBP), poly[N,N′-bis(4-butylphenyl)-N,N′-bis(phenyl)-benzidine] (poly-TPD), (poly[(9,9-dioctylfluorenyl-2,7-diyl)-co-(4,4′-(N-(4-sec-butylphenyl)diphenylamine))] (TFB), di-[4-(N,N-di-p-tolyl-amino)-phenyl]cyclohexane (TAPC), 3,5-di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, and N-(biphenyl-4-yl)-N-(4-(9-phenyl-9H-carbazol-3-yl)phenyl)biphenyl-4-amine, but it is not limited thereto. The HTL 220 may have a thickness of 30 to 150 nm, preferably 50 to 100 nm.

The ETL 240 may include an electron transporting material being at least one compound selected from the group consisting of tris-(8-hydroxyquinoline aluminum (Alq3), 2-biphenyl-4-yl-5-(4-t-butylphenyl)-1,3,4-oxadiazole (PBD), spiro-PBD, lithium quinolate (Liq), 1,3,5-tris(N-phenylbenzimidazol-2-yl)benzene (TPBi), bis(2-methyl-8-quinolinolato-N1,O8)-(1,1′-biphenyl-4-olato)aluminum (BAlq), 4,7-diphenyl-1,10-phenanthroline (Bphen), 2,9-bis(naphthalene-2-yl)-4,7-diphenyl-1,10-phenanthroline (NBphen), 2,9-dimethyl-4,7-diphenyl-1,10-phenathroline (BCP), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 1,3,5-tri(p-pyrid-3-yl-phenyl)benzene (TpPyPB), 2,4,6-tris(3′-(pyridin-3-yl)biphenyl-3-yl)1,3,5-triazine (TmPPPyTz), poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline) (TPQ), diphenyl-4-triphenylsilyl-phenylphosphine oxide (TSPO1), and 2-[4-(9,10-Di-2-naphthalen2-yl-2-anthracen-2-yl)phenyl]-1-phenyl-1H-benzimidazole (ZADN). The ETL 240 may have a thickness of 10 to 50 nm, preferably 20 to 40 nm.

The EIL 250 may include an electron injection material being at least one of LiF, CsF, NaF, BaF₂, lithium quinolate (Liq), lithium benzoate and/or sodium stearate. The EIL 250 may have a thickness of 0.1 to 10 nm, preferably 0.5 to 5 nm.

The EBL 225, which is positioned between the EML 230 and the HTL 220 to block an electron from the EML 230 to the HTL 220, may include an electron blocking material being at least one compound selected from the group consisting of TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, 1,3-bis(carbazol-9-yl)benzene (mCP), 3,3′-bis(N-carbazolyl)-1,1′-biphenyl (mCBP), CuPc, N,N′-bis[4-[bis(3-methylphenyl)amino]phenyl]-N,N′-diphenyl-[1,1′-biphenyl]-4,4′-diamine (DNTPD), TDAPB, DCDPA, and 2,8-bis(9-phenyl-9H-carbazol-3-yl)dibenzo[b,d]thiophene, but it is not limited thereto. The EBL 225 may have a thickness of 5 to 30 nm, preferably 10 to 20 nm.

The HBL 245, which is positioned between the EML 230 and the ETL 240 to block an electron from the EML 230 to the ETL 240, may include the material of the HTL 220. For example, the HBL 245 may include a hole blocking material being at least one compound selected from the group consisting of BCP, BAlq, Alq3, PBD, spiro-PBD, Liq, bis-4,6-(3,5-di-3-pyridylphenyl)-2-methylpyrimidine (B3PYMPM), bis[2-(diphenylphosphino)phenyl]ether oxide (DPEPO), 9-(6-9H-carbazol-9-yl)pyridine-3-yl)-9H-3,9′-bicarbazole and TSPO1, but it is not limited thereto. The HBL 245 may have a thickness of 1 to 20 nm, preferably 5 to 15 nm.

In the OLED D1, the red EML 230 may constitute an emitting part, or the red EML 230 and at least one of the HIL 210, the HTL 220, the EBL 225, the HBL 245, the ETL 240, and the EIL 250 may constitute the emitting part.

The red EML 230 includes a first delayed fluorescent compound 232, a second delayed fluorescent compound 234, and a fluorescent compound 236. The first delayed fluorescent compound 232 may serve as a first auxiliary dopant (or a first auxiliary host), the second delayed fluorescent compound 234 may serve as a second auxiliary dopant (or a second auxiliary host), and the fluorescent compound 236 may serve as a dopant (an emitter).

The first delayed fluorescent compound 232 is represented by Formula 1.

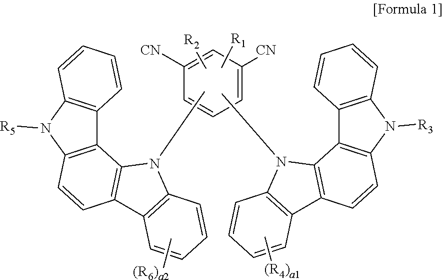

In Formula 1, each of a1 and a2 is independently an integer of 0 to 4, each of R₁ and R₂ is independently selected from the group consisting of a substituted or unsubstituted C6 to C30 aryl group and a substituted or unsubstituted C3 to C30 heteroaryl group,
each of R₃ and R₅ is independently selected from the group consisting of hydrogen, deuterium, a substituted or unsubstituted C1 to C10 alkyl group, a substituted or unsubstituted C6 to C30 aryl group and a substituted or unsubstituted C3 to C30 heteroaryl group, and
each of R₄ and R₆ is independently selected from the group consisting of a substituted or unsubstituted C1 to C10 alkyl group, a substituted or unsubstituted C1 to C10 alkoxy group, a substituted or unsubstituted C3 to C30 cycloalkyl group, a substituted or unsubstituted C6 to C30 aryl group and a substituted or unsubstituted C3 to C30 heteroaryl group.

In the present disclosure, without specific definition, a substituent of an alkyl group, an alkoxy group, a cycloalkyl group, an aryl group and a heteroaryl group may be at least one of deuterium, a substituted or unsubstituted C1 to C10 alkyl group, a substituted or unsubstituted C3 to C30 cycloalkyl group, a substituted or unsubstituted C6 to C30 aryl group and a substituted or unsubstituted C3 to C30 heteroaryl group.

In the present disclosure, without specific definition, a C1 to C10 alkyl group may be selected from the group consisting of methyl, ethyl, propyl and butyl, e.g., tert-butyl.

In the present disclosure, without specific definition, a C1 to C10 alkoxy group may be selected from the group consisting of methoxy, ethoxy, propoxy and butoxy, e.g., tert-butoxy.

In the present disclosure, without specific definition, a C3 to C30 cycloalkyl group may be selected from the group consisting of cyclopropyl, cyclobutyl and cyclohexyl.

In the present disclosure, without specific definition, a C6 to C30 aryl group may be selected from the group consisting of phenyl, biphenyl, terphenyl, naphthyl, anthracenyl, pentanenyl, indenyl, indenoindenyl, heptalenyl, biphenylenyl, indacenyl, phenanthrenyl, benzophenanthrenyl, dibenzophenanthrenyl, azulenyl, pyrenyl, fluoranthenyl, triphenylenyl, chrysenyl, tetraphenyl, tetrasenyl, picenyl, pentaphenyl, pentacenyl, fluorenyl, indenofluorenyl and spiro-fluorenyl.

In the present disclosure, without specific definition, a C3 to C30 heteroaryl group may be selected from the group consisting of pyrrolyl, pyridinyl, pyrimidinyl, pyrazinyl, pyridazinyl, triazinyl, tetrazinyl, imidazolyl, pyrazolyl, indolyl, isoindolyl, indazolyl, indolizinyl, pyrrolizinyl, carbazolyl, benzocarbazolyl, dibenzocarbazolyl, indolocarbazolyl, indenocarbazolyl, benzofurocarbazolyl, benzothienocarbazolyl, quinolinyl, isoquinolinyl, phthalazinyl, quinoxalinyl, cinnolinyl, quinazolinyl, quinozolinyl, purinyl, benzoquinolinyl, benzoisoquinolinyl, benzoquinazolinyl, benzoquinoxalinyl, acridinyl, phenanthrolinyl, perimidinyl, phenanthridinyl, pteridinyl, naphtharidinyl, furanyl, oxazinyl, oxazolyl, oxadiazolyl, triazolyl, dioxynyl, benzofuranyl, dibenzofuranyl, thiopyranyl, xanthenyl, chromanyl, isochromanyl, thioazinyl, thiophenyl, benzothiophenyl, dibenzothiophenyl, difuropyrazinyl, benzofurodibenzofuranyl, benzothienobenzothiophenyl, benzothienodibenzothiophenyl, benzothienobenzofuranyl, and benzothienodibenzofuranyl.

In an aspect of the present disclosure, each of R₁ and R₂ may be independently selected from the group consisting of a substituted or unsubstituted C6 to C30 aryl group, e.g., phenyl, biphenyl or naphthyl, and a substituted or unsubstituted C3 to C30 heteroaryl group, e.g., dibenzofuranyl, phenyldibenzofuranyl, dibenzothiophenyl or phenyldibenzothiophenyl.

In an aspect of the present disclosure, one of R₁ and R₂ may be a substituted or unsubstituted C6 to C30 aryl group, e.g., phenyl, biphenyl or naphthyl, and the other one of R₁ and R₂ may be a substituted or unsubstituted C3 to C30 heteroaryl group, e.g., dibenzofuranyl, phenyldibenzofuranyl, dibenzothiophenyl or phenyldibenzothiophenyl.

In an aspect of the present disclosure, each of a1 and a2 may be independently 0 or 1.

In an aspect of the present disclosure, each of R₄ and R₆ may be independently selected from the group consisting of a substituted or unsubstituted C1 to C10 alkyl group, e.g., methyl or tert-butyl, and a substituted or unsubstituted C6 to C30 aryl group, e.g., phenyl, biphenyl or naphthyl.

In an aspect of the present disclosure, R₄ and R₆ may be same.

In an aspect of the present disclosure, each of R₃ and R₅ may be independently selected from the group consisting of a substituted or unsubstituted C6 to C30 aryl group, e.g., phenyl, biphenyl or naphthyl.

In an aspect of the present disclosure, R₃ and R₅ may be same.

In Formula 1, positions of R₁, R₂ and two fused rings may be specified. For example, Formula 1 may be represented by Formula 1a.

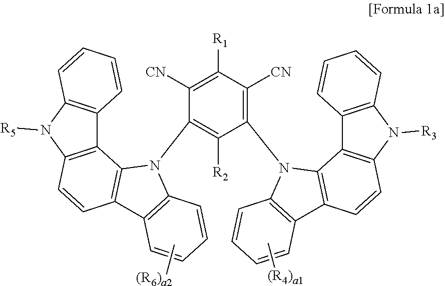

In Formula 1a, definitions of R₁ to R₆, a1 and a2 are same as those in Formula 1.

For example, the first delayed fluorescent compound 232 may be one of compounds in Formula 2.

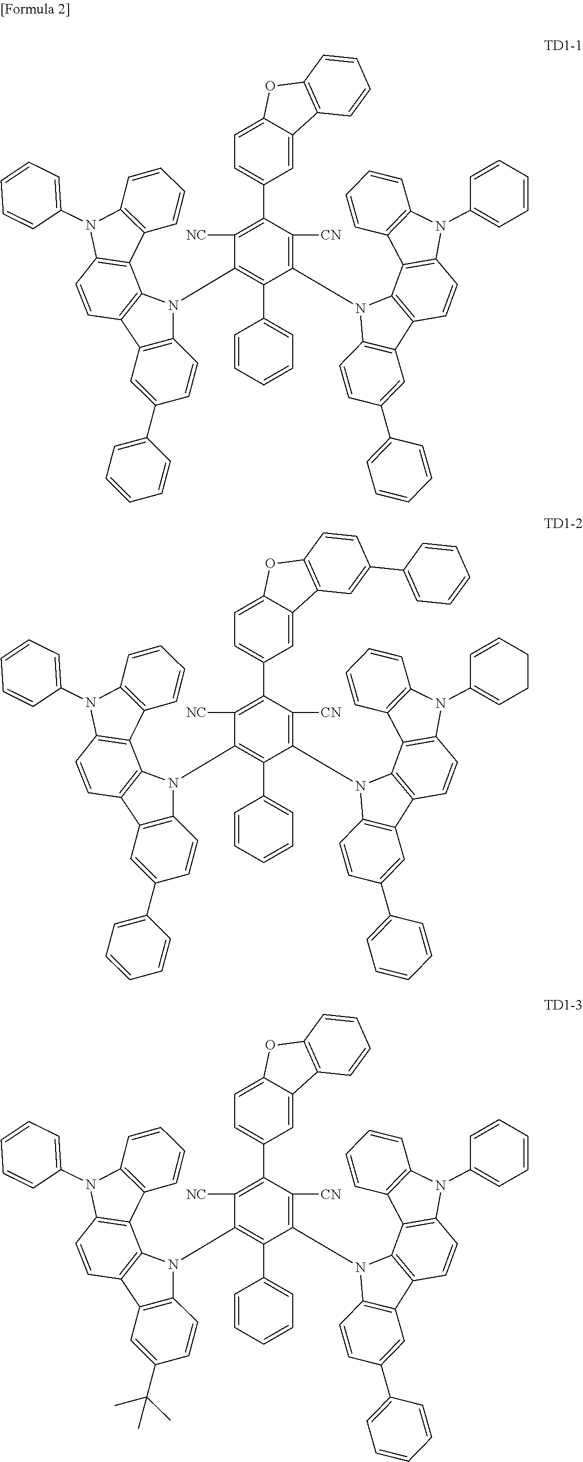

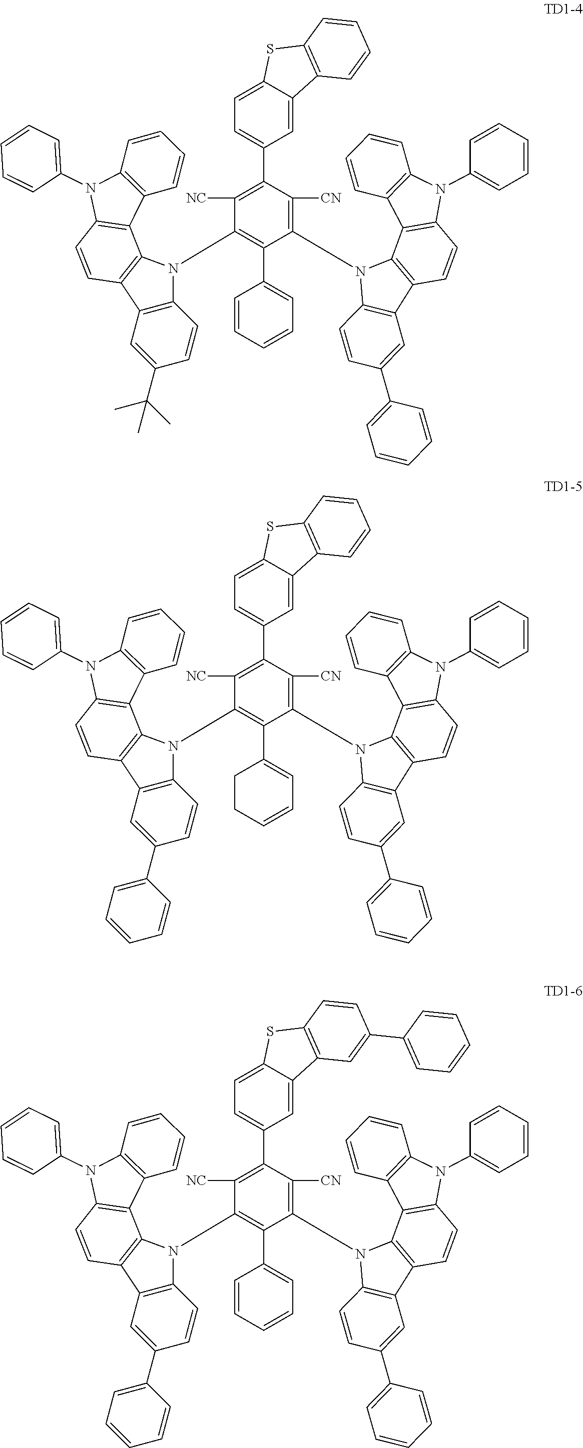 [SMILES: CC(C)(C)c1ccc2c(c1)c1ccc3c(c4ccccc4n3-c3ccccc3)c1n2-c1c(C#N)c(-c2ccc3sc4ccccc4c3c2)c(C#N)c(-n2c3ccc(-c4ccccc4)cc3c3ccc4c(c5ccccc5n4-c4ccccc4)c32)c1-c1ccccc1 ; N#Cc1c(-c2ccc3sc4ccccc4c3c2)c(C#N)c(-n2c3ccc(-c4ccccc4)cc3c3ccc4c(c5ccccc5n4-c4ccccc4)c32)c(C2=CC=CCC2)c1-n1c2ccc(-c3ccccc3)cc2c2ccc3c(c4ccccc4n3-c3ccccc3)c21 ; N#Cc1c(-c2ccc3sc4ccc(-c5ccccc5)cc4c3c2)c(C#N)c(-n2c3ccc(-c4ccccc4)cc3c3ccc4c(c5ccccc5n4-c4ccccc4)c32)c(-c2ccccc2)c1-n1c2ccc(-c3ccccc3)cc2c2ccc3c(c4ccccc4n3-c3ccccc3)c21]

The second delayed fluorescent compound 234 is represented by Formula 3.

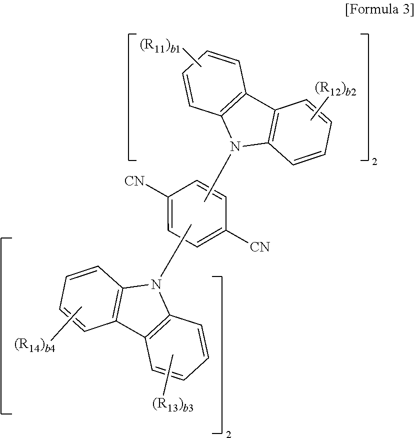

In Formula 3, each of b1 to b4 is independently an integer of 0 to 4, and
each of R₁₁ to R₁₄ is independently selected from the group consisting of a substituted or unsubstituted C1 to C10 alkyl group, a substituted or unsubstituted C1 to C10 alkoxy group, a substituted or unsubstituted C3 to C30 cycloalkyl group, a substituted or unsubstituted C6 to C30 aryl group and a substituted or unsubstituted C3 to C30 heteroaryl group.

In an aspect of the present disclosure, each of b1 to b4 may be independently 0 or 1.

In an aspect of the present disclosure, each of R₁₁ to R₁₄ may be independently selected from the group consisting of methyl, tert-butyl, methoxy, tert-butoxy, cyclohexyl, phenyl, biphenyl, naphthyl and pyridyl.

In Formula 3, two same carbazole moiety may be linked at a para-position. For example, Formula 3 may be represented by Formula 3a.

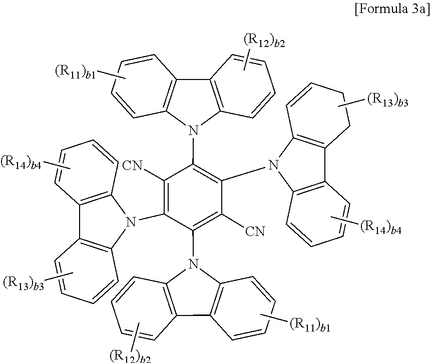

In Formula 3a, definitions of b1 to b4 and R₁₁ to R₁₄ are same as those in Formula 3.

For example, the second delayed fluorescent compound 234 may be one of compounds in Formula 4.

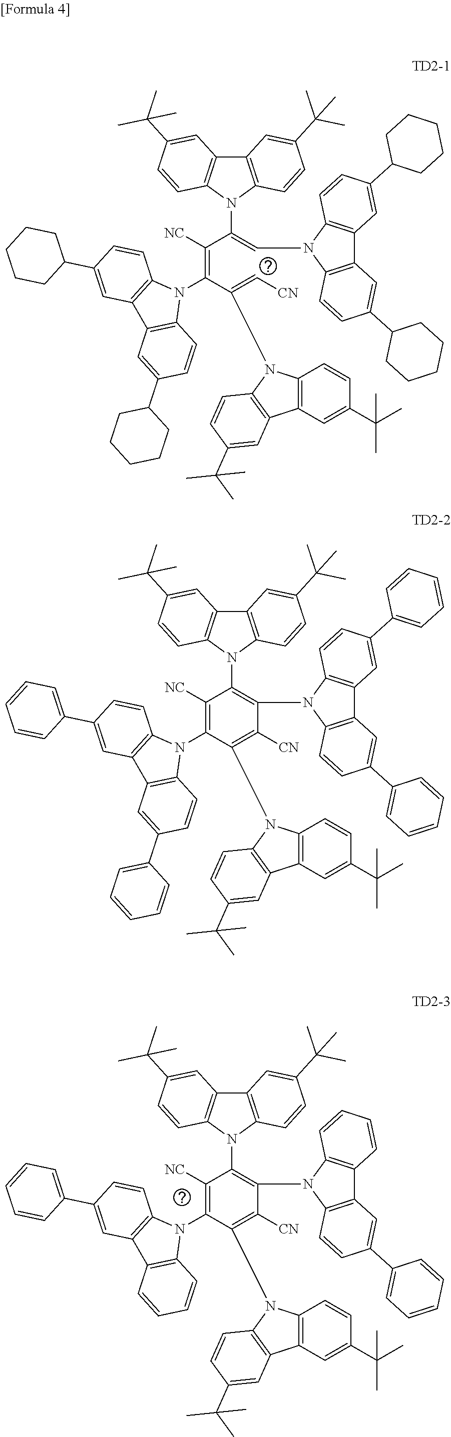

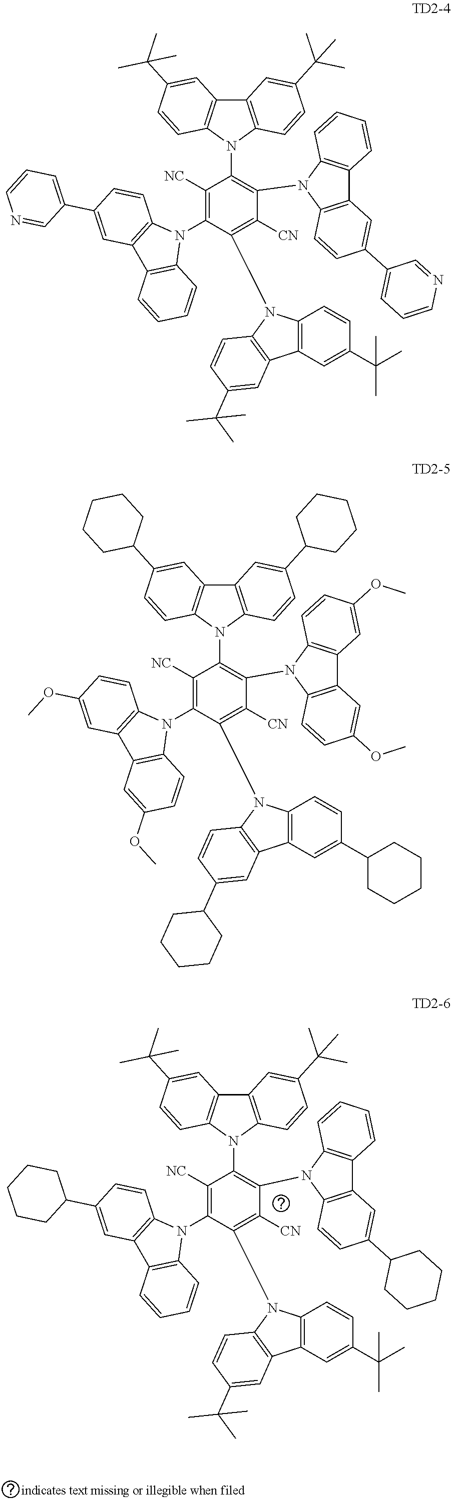 [SMILES: CC(C)(C)c1ccc2c(c1)c1cc(C(C)(C)C)ccc1n2-c1c(C#N)c(-n2c3ccccc3c3cc(-c4cccnc4)ccc32)c(-n2c3ccc(C(C)(C)C)cc3c3cc(C(C)(C)C)ccc32)c(C#N)c1-n1c2ccccc2c2cc(-c3cccnc3)ccc21 ; COc1ccc2c(c1)c1cc(OC)ccc1n2-c1c(C#N)c(-n2c3ccc(C4CCCCC4)cc3c3cc(C4CCCCC4)ccc32)c(-n2c3ccc(OC)cc3c3cc(OC)ccc32)c(C#N)c1-n1c2ccc(C3CCCCC3)cc2c2cc(C3CCCCC3)ccc21 ; CC(C)(C)c1ccc2c(c1)c1cc(C(C)(C)C)ccc1n2-c1c(C#N)c(-n2c3ccccc3c3cc(C4CCCCC4)ccc32)c(-n2c3ccc(C(C)(C)C)cc3c3cc(C(C)(C)C)ccc32)c(C#N)c1-n1c2ccccc2c2cc(C3CCCCC3)ccc21]

In one embodiment, the fluorescent compound 236 is represented by Formula 5.

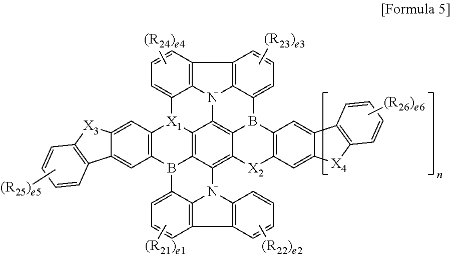

In Formula 5, each of e1 and e3 is independently an integer of 0 to 3, each of e2, e4, e5 and e6 is independently an integer of 0 to 4, and n is 0 or 1.
each of X₁, X₂, X₃, and X₄ is independently selected from the group consisting of O, S, Se, and Te, and
each of R₂₁ to R₂₆ is independently selected from the group consisting of deuterium, a substituted or unsubstituted C1 to C10 alkyl group, a substituted or unsubstituted C1 to C10 alkoxy group, a substituted or unsubstituted C3 to C30 cycloalkyl group, a substituted or unsubstituted C6 to C30 aryl group and a substituted or unsubstituted C3 to C30 heteroaryl group.

In an aspect of the present disclosure, each of e1 to e4 may be 1, and each of e5 and e6 may be 0.

In an aspect of the present disclosure, each of X₁, X₂, X₃, and X₄ may be independently O or S.

In an aspect of the present disclosure, each of X₁, X₂, X₃, and X₄ may be O.

In an aspect of the present disclosure, each of X₁, X₂, X₃, and X₄ may be S.

In an aspect of the present disclosure, each of R₂₁ to R₂₆ may be independently selected from the group consisting of a substituted or unsubstituted C1 to C10 alkyl group, e.g., methyl or tert-butyl, and a substituted or unsubstituted C1 to C10 alkoxy group, e.g., methoxy or tert-butoxy.

In Formula 5, positions of R₂₁ to R₂₄ may be specified. For example, Formula 5 may be represented by Formula 5a.

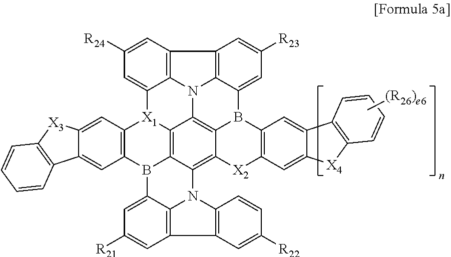

In Formula 5a, definitions of n, X₁ to X₄, and Raj to R₂₄ are same as those in Formula 5.

For example, the fluorescent compound 236 may be one of compounds in Formula 6.

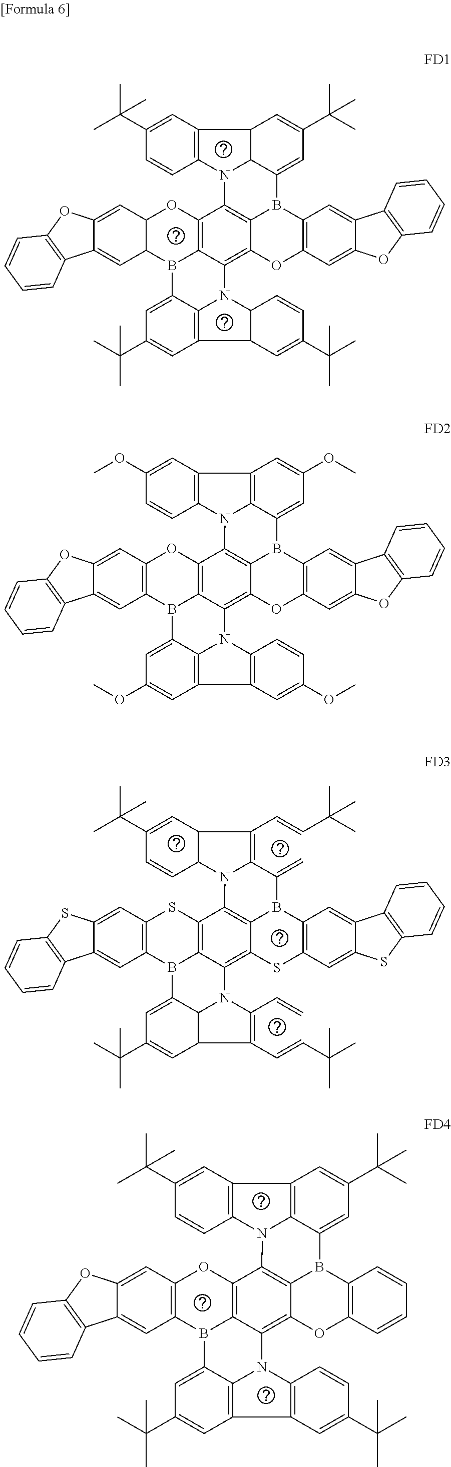

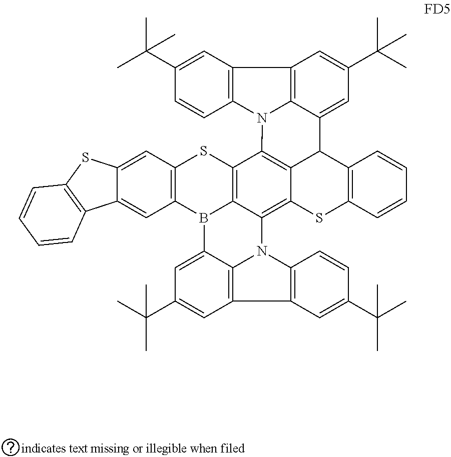 [SMILES: CC(C)(C)c1ccc2c(c1)c1cc(C(C)(C)C)cc3c1n2-c1c2c4c(c5c1B3c1cc3c(cc1S5)sc1ccccc13)-n1c3ccc(C(C)(C)C)cc3c3cc(C(C)(C)C)cc(c31)C4c1ccccc1S2]

The red EML 230 may further include a host 238. For example, the host 238 may be one of compounds in Formula 7.

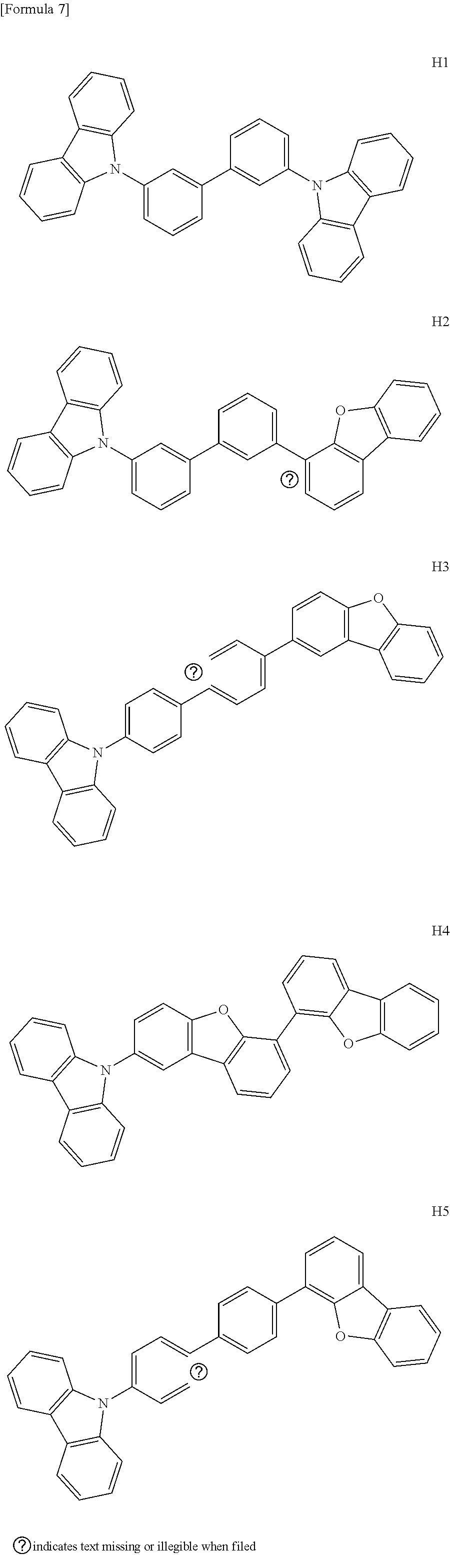 [SMILES: c1cc(-c2cccc(-n3c4ccccc4c4ccccc43)c2)cc(-n2c3ccccc3c3ccccc32)c1 ; c1cc(-c2cccc(-n3c4ccccc4c4ccccc43)c2)cc(-c2cccc3c2oc2ccccc23)c1 ; C=C/C(=C\C=C\c1ccc(-n2c3ccccc3c3ccccc32)cc1)c1ccc2oc3ccccc3c2c1 ; c1ccc2c(c1)oc1c(-c3cccc4c3oc3ccc(-n5c6ccccc6c6ccccc65)cc34)cccc12 ; C=C/C(=C\C=C\c1ccc(-c2cccc3c2oc2ccccc23)cc1)n1c2ccccc2c2ccccc21]

The red EML 230 may have a thickness of 5 to 80 nm, preferably 10 to 50 nm.

In the red EML 230, a weight % of each of the first delayed fluorescent compound 232 and the second delayed fluorescent compound 234 is greater than a weight % of the fluorescent compound 236. The weight % of the first delayed fluorescent compound 232 and the weight % of the second delayed fluorescent compound 234 may be same or different.

In the red EML 230, each of the first and second delayed fluorescent compounds 232 and 234 may have a weight % of 5 to 50, the fluorescent compound 236 may have a weight % of 0.1 to 5, and the host 238 may have a weight % of 25 to 80.

In an aspect of the present disclosure, a weight % of the host 238 may be greater than the weight % of each of the first delayed fluorescent compound 232 and the second delayed fluorescent compound 234. Namely, the weight % of each of the first delayed fluorescent compound 232 and the second delayed fluorescent compound 234 may be smaller than that of the host 238 and may be greater than that of the fluorescent compound 236.

For example, the host 238 may have a weight % of 60 to 80, each of the first and second delayed fluorescent compounds 232 and 234 may have a weight % of 5 to 30, and the fluorescent compound 236 may have a weight % of 0.1 to 5.

In an aspect of the present disclosure, a weight % of the first delayed fluorescent compounds 232 may be equal to or smaller than that of the second delayed fluorescent compounds 234.

As described above, the first delayed fluorescent compound 232 may serve as a first auxiliary dopant (or a first auxiliary host), the second delayed fluorescent compound 234 may serve as a second auxiliary dopant (or a second auxiliary host), and the fluorescent compound 236 may serve as a dopant (an emitter).

When the hole and the electron are respectively injected from the first electrode 160 and the second electrode 164 into the red EML 230, an exciton is generated in the host 238 and is transferred into the first and second delayed fluorescent compounds 232 and 234. Then, a whole or a part of the exciton of the first delayed fluorescent compound 232 is transferred into the second delayed fluorescent compound 234 so that an amount of the exciton in the second delayed fluorescent compound 234 is amplified. Finally, the exciton of the second delayed fluorescent compound 234 is transferred into the fluorescent compound 236 so that the red light is emitted from the fluorescent compound 236.

Alternatively, the red EML 230 may include only the first delayed fluorescent compound 232, the second delayed fluorescent compound 234, and the fluorescent compound 236 without the host 238. In this case, an exciton is generated in the first and second delayed fluorescent compounds 232 and 234. Then, a whole or a part of the exciton of the first delayed fluorescent compound 232 is transferred into the second delayed fluorescent compound 234 so that an amount of the exciton in the second delayed fluorescent compound 234 is amplified. Finally, the exciton of the second delayed fluorescent compound 234 is transferred into the fluorescent compound 236 so that the red light is emitted from the fluorescent compound 236.

FIG. 4 is a view illustrating an energy relation of compounds in an EML of an OLED of the present disclosure.

Referring to FIG. 4, the first delayed fluorescent compound 232 has a first lowest unoccupied molecular orbital (LUMO) energy level, and the second delayed fluorescent compound 234 has a second LUMO energy level lower than the first LUMO energy level. A difference “ΔLUMO1” between the first LUMO energy level and the second LUMO energy level may be 0.4 eV or less. (ΔLUMO1≤0.4 eV)

The first delayed fluorescent compound 232 has a first highest occupied molecular orbital (HOMO) energy level, and the second delayed fluorescent compound 234 has a second HOMO energy level lower than the first HOMO energy level. A difference “ΔHOMO” between the first HOMO energy level and the second HOMO energy level may be 0.2 eV or less. (ΔHOMO≤0.2 eV)

The difference “ΔLUMO1” between the first LUMO energy level and the second LUMO energy level may be greater than the difference “ΔHOMO” between the first HOMO energy level and the second HOMO energy level. (ΔLUMO1>ΔHOMO)

The fluorescent compound 236 has a third LUMO energy level higher than the second LUMO energy level. A difference “ΔLUMO2” between the second LUMO energy level and the third LUMO energy level may be 0.6 eV or less. (ΔLUMO230.6 eV)

The difference “ΔLUMO2” between the second LUMO energy level and the third LUMO energy level may be greater than the difference “ΔLUMO1” between the first LUMO energy level and the second LUMO energy level. (ΔLUMO2>ΔLUMO1)

An energy bandgap (Eg) of each of the first delayed fluorescent compound 232 and the second delayed fluorescent compound 234 may be in a range of 2.0 to 3.0 eV. (2.0≤Eg≤3.0)

As described above, the OLED D1 of the present disclosure is positioned in the red pixel region, and the red EML 230 includes the first delayed fluorescent compound 232 represented by Formula 1, the second delayed fluorescent compound 234 represented by Formula 3, the fluorescent compound 236 represented by Formula 5. As a result, in the OLED D1, the driving voltage is decreased, and the emitting efficiency and the lifespan are increased.

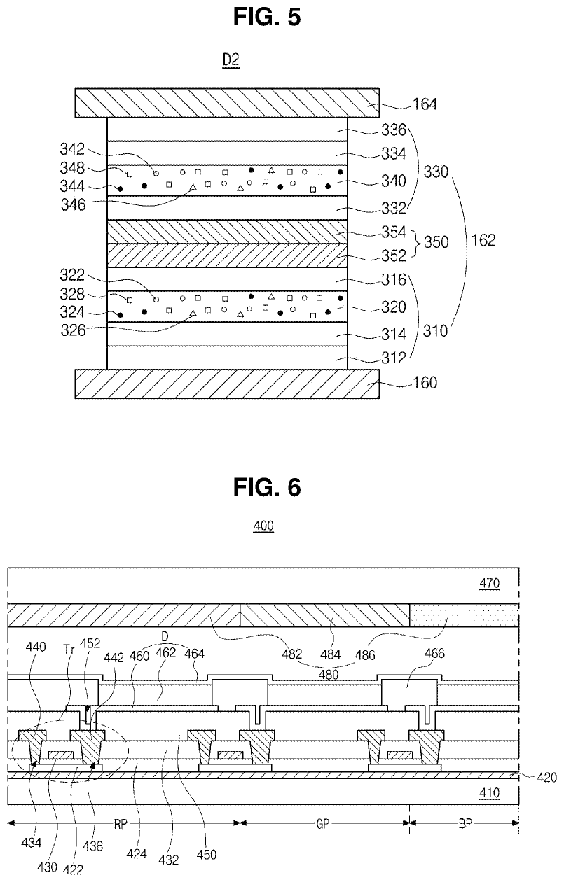

FIG. 5 is a schematic cross-sectional view illustrating an OLED according to a third embodiment of the present disclosure.

As shown in FIG. 5, the OLED D2 includes first and second electrodes 160 and 164 facing each other and the organic emitting layer 162 therebetween. The organic emitting layer 162 includes a first emitting part 310 including a first red EML 320 and a second emitting part 330 including a second red EML 340. In addition, the organic emitting layer 162 may further include a charge generation layer (CGL) 350 between the first and second emitting parts 310 and 330.

The organic light emitting display device 100 includes red, green, and blue pixel regions. In addition, the organic light emitting display device 100 may further include a white pixel region. The OLED D2 may be positioned in the red pixel region.

The first electrode 160 is an anode, and the second electrode 164 is a cathode. One of the first and second electrodes 160 and 164 is a reflective electrode, and the other one of the first and second electrodes 160 and 164 is a transparent (semitransparent) electrode.

For example, the first electrode 160 may include a transparent conductive material layer formed of ITO or IZO, and the second electrode 164 may include one of Al, Mg, Ag, AlMg, and MgAg.

The CGL 350 is positioned between the first and second emitting parts 310 and 330 so that the first emitting part 310, the CGL 350 and the second emitting part 330 are sequentially stacked on the first electrode 160. Namely, the first emitting part 310 is positioned between the first electrode 160 and the CGL 350, and the second emitting part 330 is positioned between the second electrode 164 and the CGL 350.

The first red EML 320 includes a first delayed fluorescent compound 322 represented by Formula 1, a second delayed fluorescent compound 324 represented by Formula 3, a first fluorescent compound 326 represented by Formula 5. The first red EML 320 may further include a first host 328. The first delayed fluorescent compound 322 may be one of the compounds in Formula 2, and the second delayed fluorescent compound 324 may be one of the compounds in Formula 4. The first fluorescent compound 326 may be one of the compounds in Formula 6, and the first host 328 may be one of the compounds in Formula 7.

When the first red EML 320 includes the first delayed fluorescent compound 322 represented by Formula 1 and the second delayed fluorescent compound 324 represented by Formula 3, an energy transfer efficiency to the first fluorescent compound 326 is improved. Accordingly, in the OLED D2 including the first red EML 320 and the organic light emitting display device 100 including the OLED D2, the driving voltage is decreased, and the emitting efficiency and the lifespan are increased.

The first red EML 320 may have a thickness of 5 to 80 nm, preferably 10 to 50 nm.

In the first red EML 320, a weight % of each of the first delayed fluorescent compound 322 and the second delayed fluorescent compound 324 is greater than a weight % of the first fluorescent compound 326. The weight % of the first delayed fluorescent compound 322 and the weight % of the second delayed fluorescent compound 324 may be same or different.

In the first red EML 320, each of the first and second delayed fluorescent compounds 322 and 324 may have a weight % of 5 to 50, the first fluorescent compound 326 may have a weight % of 0.1 to 5, and the first host 328 may have a weight % of 25 to 80.

In an aspect of the present disclosure, a weight % of the first host 328 may be greater than the weight % of each of the first delayed fluorescent compound 322 and the second delayed fluorescent compound 324. Namely, the weight % of each of the first delayed fluorescent compound 322 and the second delayed fluorescent compound 324 may be smaller than that of the first host 328 and may be greater than that of the first fluorescent compound 326.

For example, the first host 328 may have a weight % of 60 to 80, each of the first and second delayed fluorescent compounds 322 and 324 may have a weight % of 5 to 30, and the first fluorescent compound 326 may have a weight % of 0.1 to 5.

In an aspect of the present disclosure, a weight % of the first delayed fluorescent compounds 322 may be equal to or smaller than that of the second delayed fluorescent compounds 324.

The first delayed fluorescent compound 322 has a first LUMO energy level, and the second delayed fluorescent compound 324 has a second LUMO energy level lower than the first LUMO energy level. A difference “ΔLUMO1” between the first LUMO energy level and the second LUMO energy level may be 0.4 eV or less. (ΔLUMO1≤0.4 eV)

The first delayed fluorescent compound 322 has a first HOMO energy level, and the second delayed fluorescent compound 324 has a second HOMO energy level lower than the first HOMO energy level. A difference “A HOMO” between the first HOMO energy level and the second HOMO energy level may be 0.2 eV or less. (ΔHOMO≤0.2 eV)

The difference “ΔLUMO1” between the first LUMO energy level and the second LUMO energy level may be greater than the difference “ΔHOMO” between the first HOMO energy level and the second HOMO energy level. (ΔLUMO1>ΔHOMO)

The first fluorescent compound 326 has a third LUMO energy level higher than the second LUMO energy level. A difference “ΔLUMO2” between the second LUMO energy level and the third LUMO energy level may be 0.6 eV or less. (ΔLUMO2≤0.6 eV) The difference “ΔLUMO2” between the second LUMO energy level and the third LUMO energy level may be greater than the difference “ΔLUMO1” between the first LUMO energy level and the second LUMO energy level. (ΔLUMO2>ΔLUMO1)

An energy bandgap (Eg) of each of the first delayed fluorescent compound 322 and the second delayed fluorescent compound 324 may be in a range of 2.0 to 3.0 eV. (2.0≤Eg≤3.0)

The first emitting part 310 may further include at least one of a first HTL 314 under the first red EML 320 and a first ETL 316 on or over the first red EML 320. Namely, the first HTL 314 is disposed between the first red EML 320 and the first electrode 160, and the first ETL 316 is disposed between the first red EML 320 and the CGL 350.

In addition, the first emitting part 310 may further include an HIL 312 between the first electrode 160 and the first HTL 314.

Moreover, the first emitting part 310 may further include at least one of a first EBL between the first HTL 314 and the first red EML 320 and the first HBL between the first red EML 320 and the first ETL 316.

The second red EML 340 includes a third delayed fluorescent compound 342 represented by Formula 1, a fourth delayed fluorescent compound 344 represented by Formula 3, a second fluorescent compound 346 represented by Formula 5. The second red EML 340 may further include a second host 348. The third delayed fluorescent compound 342 may be one of the compounds in Formula 2, and the fourth delayed fluorescent compound 344 may be one of the compounds in Formula 4. The second fluorescent compound 346 may be one of the compounds in Formula 6, and the second host 348 may be one of the compounds in Formula 7.

When the second red EML 340 includes the third delayed fluorescent compound 342 represented by Formula 1 and the fourth delayed fluorescent compound 344 represented by Formula 3, an energy transfer efficiency to the second fluorescent compound 346 is improved. Accordingly, in the OLED D2 including the second red EML 340 and the organic light emitting display device 100 including the OLED D2, the driving voltage is decreased, and the emitting efficiency and the lifespan are increased.

The second red EML 340 may have a thickness of 5 to 80 nm, preferably 10 to 50 nm.

In the second red EML 340, a weight % of each of the third delayed fluorescent compound 342 and the fourth delayed fluorescent compound 344 is greater than a weight % of the second fluorescent compound 346. The weight % of the third delayed fluorescent compound 342 and the weight % of the fourth delayed fluorescent compound 344 may be same or different.

In the second red EML 340, each of the third and fourth delayed fluorescent compounds 342 and 344 may have a weight % of 5 to 50, the second fluorescent compound 346 may have a weight % of 0.1 to 5, and the second host 348 may have a weight % of 25 to 80.

In an aspect of the present disclosure, a weight % of the second host 348 may be greater than the weight % of each of the third delayed fluorescent compound 342 and the fourth delayed fluorescent compound 344. Namely, the weight % of each of the third delayed fluorescent compound 342 and the fourth delayed fluorescent compound 344 may be smaller than that of the second host 348 and may be greater than that of the second fluorescent compound 346.

For example, the second host 348 may have a weight % of 60 to 80, each of the third and fourth delayed fluorescent compounds 342 and 344 may have a weight % of 5 to 30, and the second fluorescent compound 346 may have a weight % of 0.1 to 5.

In an aspect of the present disclosure, a weight % of the third delayed fluorescent compounds 342 may be equal to or smaller than that of the fourth delayed fluorescent compounds 344.

The third delayed fluorescent compound 342 has a fourth LUMO energy level, and the fourth delayed fluorescent compound 344 has a fifth LUMO energy level lower than the fourth LUMO energy level. A difference between the fourth LUMO energy level and the fifth LUMO energy level may be 0.4 eV or less.

The third delayed fluorescent compound 342 has a third HOMO energy level, and the fourth delayed fluorescent compound 344 has a fourth HOMO energy level lower than the third HOMO energy level. A difference between the third HOMO energy level and the fourth HOMO energy level may be 0.2 eV or less.

The difference between the fourth LUMO energy level and the fifth LUMO energy level may be greater than the difference between the third HOMO energy level and the fourth HOMO energy level.

The second fluorescent compound 346 has a sixth LUMO energy level high than the fifth LUMO energy level. A difference between the fifth LUMO energy level and the sixth LUMO energy level may be 0.6 eV or less.

The difference between the fifth LUMO energy level and the sixth LUMO energy level may be greater than the difference between the fourth LUMO energy level and the fifth LUMO energy level.

An energy bandgap (Eg) of each of the third delayed fluorescent compound 342 and the fourth delayed fluorescent compound 344 may be in a range of 2.0 to 3.0 eV.

The second emitting part 330 may further include at least one of a second HTL 332 under the second red EML 340 and a second ETL 334 on or over the second red EML 340. Namely, the second HTL 332 is disposed between the second red EML 340 and the CGL 350, and the second ETL 334 is disposed between the second red EML 340 and the second electrode 164.

In addition, the second emitting part 330 may further include an EIL 336 between the second ETL 334 and the second electrode 164.

Moreover, the second emitting part 330 may further include at least one of a second EBL between the second HTL 332 and the second red EML 340 and the second HBL between the second red EML 340 and the second ETL 334.

The HIL 312 may include the above-mentioned hole injection material and may have a thickness of 1 to 20 nm, preferably 5 to 15 nm. Each of the first and second HTLs 314 and 332 may include the above-mentioned hole transporting material and may have a thickness of 30 to 150 nm, preferably 50 to 100 nm.

Each of the first and second ETLs 316 and 334 may include the above-mentioned electron transporting material and may have a thickness of 10 to 50 nm, preferably 20 to 40 nm. The EIL 336 may include the above-mentioned electron injection material and may have a thickness of 0.1 to 10 nm, preferably 0.5 to 5 nm.

Each of the first and second EBLs may include the above-mentioned electron blocking material and may have a thickness of 5 to 30 nm, preferably 10 to 20 nm. Each of the first and second HBLs may include the above-mentioned hole blocking material and may have a thickness of 1 to 20 nm, preferably 5 to 15 nm.

The CGL 350 is positioned between the first and second emitting parts 310 and 330. Namely, the first and second emitting parts 310 and 330 are connected to each other through the CGL 350. The CGL 350 may be a P—N junction type CGL of an N-type CGL 352 and a P-type CGL 354.

The N-type CGL 352 is positioned between the first ETL 316 and the second HTL 332, and the P-type CGL 354 is positioned between the N-type CGL 352 and the second HTL 332.

The N-type CGL 352 may be an organic layer doped with an alkali metal, e.g., Li, Na, K and Cs, and/or an alkali earth metal, e.g., Mg, Sr, Ba and Ra. For example, the N-type CGL 352 may be formed of an N-type charge generation material including a host being the organic material, e.g., 4,7-dipheny-1,10-phenanthroline (Bphen) and MTDATA; a dopant being an alkali metal and/or an alkali earth metal, and the dopant may be doped with a weight % of 0.01 to 30.

The P-type CGL 354 may be formed of a P-type charge generation material including an inorganic material, e.g., tungsten oxide (WOx), molybdenum oxide (MoOx), beryllium oxide (Be₂O₃) and vanadium oxide (V₂O₅); an organic material, e.g., NPD, HAT-CN, F4TCNQ, TPD, TNB, TCTA and N,N′-dioctyl-3,4,9,10-perylenedicarboximide (PTCDI-C8).

In FIG. 5, each of the first second red EMLs 320 and 340 includes a delayed fluorescent compound represented by Formula 1, a delayed fluorescent compound represented by Formula 3, a fluorescent compound represented by Formula 5 and a host being a compound in Formula 7. Alternatively, one of the first second red EMLs 320 and 340 includes the delayed fluorescent compound represented by Formula 1, the delayed fluorescent compound represented by Formula 3, the fluorescent compound represented by Formula 5 and the host being a compound in Formula 7, and the other one of the first or second red EMLs 320 and 340 may include a host and a phosphorescent compound as a dopant.

As described above, the OLED D2 is positioned in the red pixel region, and at least one of the first and second red EMLs 320 and 340 includes the delayed fluorescent compound represented by Formula 1, the delayed fluorescent compound represented by Formula 3 and the fluorescent compound represented by Formula 5. As a result, in the OLED D2, the driving voltage is decreased, and the emitting efficiency and the lifespan are increased.

FIG. 6 is a cross-sectional view illustrating an organic light emitting display device according to a fourth embodiment of the present disclosure.

As illustrated in FIG. 6, the organic light emitting display device 400 includes a first substrate 410, where a red pixel region RP, a green pixel region GP, and a blue pixel region BP are defined, a second substrate 470 facing the first substrate 410; an OLED D, which is positioned between the first and second substrates 410 and 470 and providing white emission, and a color filter layer 480 between the OLED D and the second substrate 470.

Each of the first and second substrates 410 and 470 may be a glass substrate or a flexible substrate. For example, the flexible substrate may be a polyimide (PI) substrate, a polyethersulfone (PES) substrate, a polyethylenenaphthalate (PEN) substrate, a polyethylene terephthalate (PET) substrate or a polycarbonate (PC) substrate.

A buffer layer 420 is formed on the substrate, and the TFT Tr corresponding to each of the red, green and blue pixel regions RP, GP and BP is formed on the buffer layer 420. The buffer layer 420 may be omitted.

A semiconductor layer 422 is formed on the buffer layer 420. The semiconductor layer 422 may include an oxide semiconductor material or polycrystalline silicon.

A gate insulating layer 424 is formed on the semiconductor layer 422. The gate insulating layer 424 may be formed of an inorganic insulating material such as silicon oxide or silicon nitride.

A gate electrode 430, which is formed of a conductive material, e.g., metal, is formed on the gate insulating layer 424 to correspond to a center of the semiconductor layer 422.

An interlayer insulating layer 432, which is formed of an insulating material, is formed on the gate electrode 430. The interlayer insulating layer 432 may be formed of an inorganic insulating material, e.g., silicon oxide or silicon nitride, or an organic insulating material, e.g., benzocyclobutene or photo-acryl.

The interlayer insulating layer 432 includes first and second contact holes 434 and 436 exposing both sides of the semiconductor layer 422. The first and second contact holes 434 and 436 are positioned at both sides of the gate electrode 430 to be spaced apart from the gate electrode 430.

A source electrode 440 and a drain electrode 442, which are formed of a conductive material, e.g., metal, are formed on the interlayer insulating layer 432.

The source electrode 440 and the drain electrode 442 are spaced apart from each other with respect to the gate electrode 430 and respectively contact both sides of the semiconductor layer 422 through the first and second contact holes 434 and 436.

The semiconductor layer 422, the gate electrode 430, the source electrode 440 and the drain electrode 442 constitute the TFT Tr. The TFT Tr serves as a driving element. Namely, the TFT Tr may correspond to the driving TFT Td (of FIG. 1).

Although not shown, the gate line and the data line cross each other to define the pixel region, and the switching TFT is formed to be connected to the gate and data lines. The switching TFT is connected to the TFT Tr as the driving element.

In addition, the power line, which may be formed to be parallel to and spaced apart from one of the gate and data lines, and the storage capacitor for maintaining the voltage of the gate electrode of the TFT Tr in one frame may be further formed.

A planarization layer 450, which includes a drain contact hole 452 exposing the drain electrode 442 of the TFT Tr, is formed to cover the TFT Tr.

A first electrode 460, which is connected to the drain electrode 442 of the TFT Tr through the drain contact hole 452, is separately formed in each pixel region and on the planarization layer 450. The first electrode 460 may be an anode and may be formed of a conductive material, e.g., a transparent conductive oxide (TCO), having a relatively high work function. The first electrode 460 may further include a reflection electrode or a reflection layer. For example, the reflection electrode or the reflective layer may include Ag or aluminum-palladium-copper (APC). In a top-emission type organic light emitting display device 400, the first electrode 460 may have a double-layered structure of Ag/ITO or APC/ITO or a triple-layered structure of ITO/Ag/ITO or ITO/APC/ITO.

A bank layer 466 is formed on the planarization layer 450 to cover an edge of the first electrode 460. Namely, the bank layer 466 is positioned at a boundary of the pixel region and exposes a center of the first electrode 460 in the pixel region. Since the OLED D emits the white light in the red, green and blue pixel regions RP, GP, and BP, the organic emitting layer 462 may be formed as a common layer in the red, green and blue pixel regions RP, GP, and BP without separation. The bank layer 466 may be formed to prevent a current leakage at an edge of the first electrode 460 and may be omitted.

An organic emitting layer 462 is formed on the first electrode 460. As illustrated below, the organic emitting layer 462 includes at least two emitting parts, and each emitting part includes at least one EML. As a result, the OLED D emits the white light.

In this case, at least one of a plurality of EMLs includes a first delayed fluorescent compound represented by Formula 1, a second delayed fluorescent compound represented by Formula 3, and a fluorescent compound represented by Formula 5 and emits red light.

A second electrode 464 is formed over the substrate 410 where the organic emitting layer 462 is formed. In the organic light emitting display device 400, since the light emitted from the organic emitting layer 462 is incident to the color filter layer 480 through the second electrode 464, the second electrode 464 has a thin profile for transmitting the light.

The first electrode 460, the organic emitting layer 462, and the second electrode 464 constitute the OLED D.

The color filter layer 480 is positioned over the OLED D and includes a red color filter 482, a green color filter 484 and a blue color filter 486 respectively corresponding to the red, green, and blue pixel regions RP, GP, and BP. The red color filter 482 may include at least one of red dye and red pigment, the green color filter 484 may include at least one of green dye and green pigment, and the blue color filter 486 may include at least one of blue dye and blue pigment.

An encapsulation layer may be formed to prevent penetration of moisture into the OLED D. For example, the encapsulation layer may include a first inorganic insulating layer, an organic insulating layer and a second inorganic insulating layer sequentially stacked, but it is not limited thereto.

The color filter layer 480 may be attached to the OLED D by using an adhesive layer. Alternatively, the color filter layer 480 may be formed directly on the OLED D or the encapsulation layer.

A polarization plate (not shown) for reducing an ambient light reflection may be disposed at an outer side of the second substrate 470. For example, the polarization plate may be a circular polarization plate.

In the OLED of FIG. 6, the first and second electrodes 460 and 464 are a reflection electrode and a transparent (or semi-transparent) electrode, respectively, and the color filter layer 480 is disposed over the OLED D. Alternatively, when the first and second electrodes 460 and 464 are a transparent (or semi-transparent) electrode and a reflection electrode, respectively, the color filter layer 480 may be disposed between the OLED D and the first substrate 410.

A color conversion layer (not shown) may be formed between the OLED D and the color filter layer 480. The color conversion layer may include a red color conversion layer, a green color conversion layer and a blue color conversion layer respectively corresponding to the red, green and blue pixel regions RP, GP, and BP. The white light from the OLED D is converted into the red light, the green light and the blue light by the red, green and blue color conversion layer, respectively. For example, the color conversion layer may include a quantum dot. Accordingly, the color purity of the organic light emitting display device 400 may be further improved.

The color conversion layer may be included instead of the color filter layer 480.

As described above, in the organic light emitting display device 400, the OLED D in the red, green, and blue pixel regions RP, GP, and BP emits the white light, and the white light from the organic light emitting diode D passes through the red color filter 482, the green color filter 484, and the blue color filter 486. As a result, the red light, the green light, and the blue light are provided from the red pixel region RP, the green pixel region GP and the blue pixel region BP, respectively.

In FIG. 6, the OLED D emitting the white light is used for a display device. Alternatively, the OLED D may be formed on an entire surface of a substrate without at least one of the driving element and the color filter layer to be used for a lightening device. The display device and the lightening device each including the OLED D of the present disclosure may be referred to as an organic light emitting device.

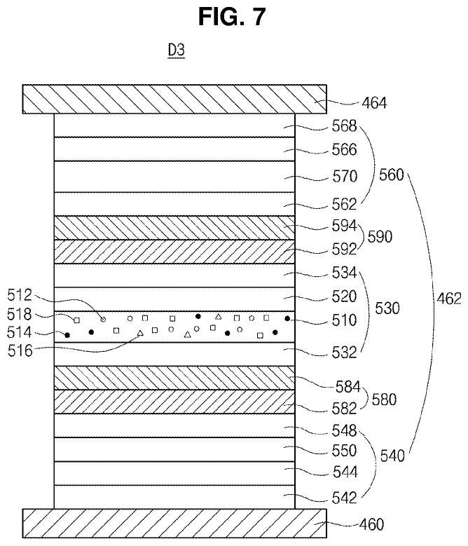

FIG. 7 is a schematic cross-sectional view illustrating an OLED according to a fifth embodiment of the present disclosure.

As shown in FIG. 7, in the OLED D3, the organic emitting layer 462 includes a first emitting part 530 including a red EML 510, a second emitting part 540 including a first blue EML 550 and a third emitting part 560 including a second blue EML 570. In addition, the organic emitting layer 462 may further include a first CGL 580 between the first and second emitting parts 530 and 540 and a second CGL 590 between the first and third emitting part 530 and 560. In addition, the first emitting part 530 may further include a green EML 520.

The organic light emitting display device 400 includes red, green and blue pixel regions, and the OLED D3 may be positioned in the red, green, and blue pixel regions.

The first electrode 460 is an anode, and the second electrode 464 is a cathode. One of the first and second electrodes 460 and 464 is a reflective electrode, and the other one of the first and second electrodes 460 and 464 is a transparent (semitransparent) electrode.

For example, the first electrode 460 may include a transparent conductive material layer formed of ITO or IZO, and the second electrode 464 may include one of Al, Mg, Ag, AlMg, and MgAg.

The second emitting part 540 is positioned between the first electrode 460 and the first emitting part 530, and the third emitting part 560 is positioned between the first emitting part 530 and the second electrode 464. In addition, the second emitting part 540 is positioned between the first electrode 460 and the first CGL 580, and the third emitting part 560 is positioned between the second CGL 590 and the second electrode 464. Namely, the second emitting part 540, the first CGL 580, the first emitting part 530, the second CGL 590 and the third emitting part 560 are sequentially stacked on the first electrode 460.

In the first emitting part 530, the green EML 520 is positioned on the red EML 510.

The red EML 510 includes a first delayed fluorescent compound 512 represented by Formula 1, a second delayed fluorescent compound 514 represented by Formula 3, a first fluorescent compound 516 represented by Formula 5. The red EML 510 may further include a first host 518. The first delayed fluorescent compound 512 may be one of the compounds in Formula 2, and the second delayed fluorescent compound 514 may be one of the compounds in Formula 4. The first fluorescent compound 516 may be one of the compounds in Formula 6, and the first host 518 may be one of the compounds in Formula 7.

When the red EML 510 includes the first delayed fluorescent compound 512 represented by Formula 1 and the second delayed fluorescent compound 514 represented by Formula 3, an energy transfer efficiency to the first fluorescent compound 516 is improved. Accordingly, in the OLED D3 including the red EML 510 and the organic light emitting display device 400 including the OLED D3, the driving voltage is decreased, and the emitting efficiency and the lifespan are increased.

The red EML 510 may have a thickness of 5 to 80 nm, preferably 10 to 50 nm.

In the red EML 510, a weight % of each of the first delayed fluorescent compound 512 and the second delayed fluorescent compound 514 is greater than a weight % of the first fluorescent compound 516. The weight % of the first delayed fluorescent compound 512 and the weight % of the second delayed fluorescent compound 514 may be same or different.

In the red EML 510, each of the first and second delayed fluorescent compounds 512 and 514 may have a weight % of 5 to 50, the first fluorescent compound 516 may have a weight % of 0.1 to 5, and the first host 518 may have a weight % of 25 to 80.

In an aspect of the present disclosure, a weight % of the first host 518 may be greater than the weight % of each of the first delayed fluorescent compound 512 and the second delayed fluorescent compound 514. Namely, the weight % of each of the first delayed fluorescent compound 512 and the second delayed fluorescent compound 514 may be smaller than that of the first host 518 and may be greater than that of the first fluorescent compound 516.

For example, the first host 518 may have a weight % of 60 to 80, each of the first and second delayed fluorescent compounds 512 and 514 may have a weight % of 5 to 30, and the first fluorescent compound 516 may have a weight % of 0.1 to 5.

In an aspect of the present disclosure, a weight % of the first delayed fluorescent compounds 512 may be equal to or smaller than that of the second delayed fluorescent compounds 514.

The first delayed fluorescent compound 512 has a first LUMO energy level, and the second delayed fluorescent compound 514 has a second LUMO energy level lower than the first LUMO energy level. A difference “ΔLUMO1” between the first LUMO energy level and the second LUMO energy level may be 0.4 eV or less. (ΔLUMO1≤0.4 eV)

The first delayed fluorescent compound 512 has a first HOMO energy level, and the second delayed fluorescent compound 514 has a second HOMO energy level lower than the first HOMO energy level. A difference “A HOMO” between the first HOMO energy level and the second HOMO energy level may be 0.2 eV or less. (ΔHOMO≤0.2 eV)

The difference “ΔLUMO1” between the first LUMO energy level and the second LUMO energy level may be greater than the difference “ΔHOMO” between the first HOMO energy level and the second HOMO energy level. (ΔLUMO1>ΔHOMO)

The first fluorescent compound 516 has a third LUMO energy level high than the second LUMO energy level. A difference “ΔLUMO2” between the second LUMO energy level and the third LUMO energy level may be 0.6 eV or less. (ΔLUMO2≤0.6 eV)

The difference “ΔLUMO2” between the second LUMO energy level and the third LUMO energy level may be greater than the difference “ΔLUMO1” between the first LUMO energy level and the second LUMO energy level. (ΔLUMO2>ΔLUMO1)

An energy bandgap (Eg) of each of the first delayed fluorescent compound 512 and the second delayed fluorescent compound 514 may be in a range of 2.0 to 3.0 eV. (2.0≤Eg≤3.0)

The green EML 520 includes a green host and a green dopant. The green EML 520 may have a thickness of 5 to 80 nm, preferably 10 to 50 nm.

The green host may be a green host material being one of mCP-CN, CBP, mCBP, mCP, DPEPO, 2,8-bis(diphenylphosphoryl)dibenzothiophene (PPT), TmPyPB, PYD-2Cz, 2,8-di(9H-carbazol-9-yl)dibenzothiophene (DCzDBT), 3′,5′-di(carbazol-9-yl)-[1,1′-bipheyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, and 9-(9-phenyl-9H-carbazol-6-yl)-9H-carbazole (CCP), but it is not limited thereto.

The green dopant may be a green dopant material being one of [bis(2-phenylpyridine)](pyridyl-2-benzofuro[2,3-b]pyridine)iridium, tris[2-phenylpyridine]iridium(III) (Ir(ppy)₃), fac-tris(2-phenylpyridine)iridium(III) (fac-Ir(ppy)₃), bis(2-phenylpyridine)(acetylacetonate)iridium(III) (Ir(ppy)₂(acac)), tris[2-(p-tolyl)pyridine]iridium(III) (Ir(mppy)₃), bis(2-(naphthalene-2-yl)pyridine)(acetylacetonate)iridium(III) (Ir(npy)₂acac), tris(2-phenyl-3-methyl-pyridine)iridium (Ir(3mppy)₃), and fac-tris(2-(3-p-xylyl)phenyl)pyridine iridium(III) (TEG), but it is not limited thereto.

The first emitting part 530 may further include at least one of a first HTL 532 under the red EML 510 and a first ETL 534 over the red EML 510. When the first emitting part 530 includes the green EML 520, the first ETL 534 is positioned on the green EML 520.

The first emitting part 530 may further include at least one of a first EBL between the red EML 510 and the first HTL 532 and a first HBL between the green EML 520 and the first ETL 534.

The second emitting part 540 may further include at least one of a second HTL 544 under the first blue EML 550 and a second ETL 548 over the first blue EML 550. In addition, the second emitting part 540 may further include an HIL 542 between the first electrode 460 and the first HTL 544.

The second emitting part 540 may further include at least one of a second EBL between the second HTL 544 and the first blue EML 550 and a second HBL between the first blue EML 550 and the second ETL 548.

The third emitting part 560 may further include at least one of a third HTL 562 under the second blue EML 570 and a third ETL 566 over the second blue EML 570. In addition, the third emitting part 560 may further include an EIL 568 between the second electrode 464 and the third ETL 566.

The third emitting part 560 may further include at least one of a third EBL between the third HTL 562 and the second blue EML 570 and a third HBL between the second blue EML 570 and the third ETL 566.

The first blue EML 550 in the second emitting part 540 includes a first blue host and a first blue dopant, and the second blue EML 570 in the third emitting part 560 includes a second blue host and a second blue dopant.

For example, each of the first and second blue hosts may be independently selected from the group consisting of mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1), 3,5-Di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), bis(2-methylphenyl)diphenylsilane (UGH-1), 1,4-bis(triphenylsilyl)benzene (UGH-2), 1,3-bis(triphenylsilyl)benzene (UGH-3), 9,9-spiorobifluoren-2-yl-diphenyl-phosphine oxide (SPPO1) and 9,9′-(5-(triphenylsilyl)-1,3-phenylene)bis(9H-carbazole) (SimCP).

For example, each of the first and second blue dopants may be independently selected from the group consisting of perylene, 4,4′-bis[4-(di-p-tolylamino)styryl]biphenyl (DPAVBi), 4-(di-p-tolylamino)-4-4′-[(di-p-tolylamino)styryl]stilbene (DPAVB), 4,4′-bis[4-(diphenylamino)styryl]biphenyl (BDAVBi), 2,7-bis(4-diphenylamino)styryl)-9,9-spiorfluorene (spiro-DPVBi), [1,4-bis[2-[4-[N,N-di(p-tolyl)amino]phenyl]vinyl] benzene (DSB), 1-4-di-[4-(N,N-diphenyl)amino]styryl-benzene (DSA), 2,5,8,11-tetra-tetr-butylperylene (TBPe), bis(2-hydroxylphenyl)-pyridine)beryllium (Bepp2), 9-(9-Phenylcarbazole-3-yl)-10-(naphthalene-1-yl)anthracene (PCAN), mer-tris(1-phenyl-3-methylimidazolin-2-ylidene-C,C(2)′iridium(III) (mer-Ir(pmi)₃), fac-Tris(1,3-diphenyl-benzimidazolin-2-ylidene-C,C(2)′iridium(III) (fac-Ir(dpbic)₃), bis(3,4,5-trifluoro-2-(2-pyridyl)phenyl-(2-carboxypyridyl)iridium(III) (Ir(tfpd)₂pic), tris(2-(4,6-difluorophenyl)pyridine))iridium(III) (Ir(Fppy)₃) and bis[2-(4,6-difluorophenyl)pyridinato-C2,N](picolinato)iridium(III) (FIrpic).

The HIL 542 may include the above-mentioned hole injection material and may have a thickness of 1 to 20 nm, preferably 5 to 15 nm. Each of the first to third HTLs 532, 544 and 564 may include the above-mentioned hole transporting material and may have a thickness of 30 to 150 nm, preferably 50 to 100 nm.

Each of the first to third ETLs 534, 548 and 566 may include the above-mentioned electron transporting material and may have a thickness of 10 to 50 nm, preferably 20 to 40 nm. The EIL 568 may include the above-mentioned electron injection material and may have a thickness of 0.1 to 10 nm, preferably 0.5 to 5 nm.

Each of the first to third EBLs may include the above-mentioned electron blocking material and may have a thickness of 5 to 30 nm, preferably 10 to 20 nm. Each of the first to third HBLs may include the above-mentioned hole blocking material and may have a thickness of 1 to 20 nm, preferably 5 to 15 nm.

The first CGL 580 is positioned between the first and second emitting parts 530 and 540, and the second CGL 590 is positioned between the first and third emitting parts 530 and 560. Namely, the first and second emitting parts 530 and 540 is connected to each other by the first CGL 580, and the first and third emitting parts 530 and 560 is connected to each other by the second CGL 590. The first CGL 580 may be a P-N junction type CGL of an N-type CGL 582 and a P-type CGL 584, and the second CGL 590 may be a P-N junction type CGL of an N-type CGL 592 and a P-type CGL 594.

In the first CGL 580, the N-type CGL 582 is positioned between the first HTL 532 and the second ETL 548, and the P-type CGL 584 is positioned between the N-type CGL 582 and the first HTL 532.

In the second CGL 590, the N-type CGL 592 is positioned between the first ETL 534 and the third HTL 562, and the P-type CGL 594 is positioned between the N-type CGL 592 and the third HTL 562.

Each of the N-type CGL 582 of the first CGL 580 and the N-type CGL 592 of the second CGL 590 may include the above-mentioned N-type charge generation material, and each of the P-type CGL 584 of the first CGL 580 and the P-type CGL 594 of the second CGL 590 may include the above-mentioned P-type charge generation material.

As illustrated above, the OLED D3 of the present disclosure includes the first emitting part 530 including the red EML 510 and the green EML 520, the second emitting part 540 including the first blue EML 550 and the third emitting part 560 including the second blue EML 570. As a result, the OLED D3 emits the white light.

In addition, the red EML 510 includes the first delayed fluorescent compound 512, which is represented by Formula 1, the second delayed fluorescent compound 514, which is represented by Formula 3, and the first fluorescent compound 516, which is represented by Formula 5. As a result, the OLED D3 has advantages in the driving voltage, the emitting efficiency and the lifespan.

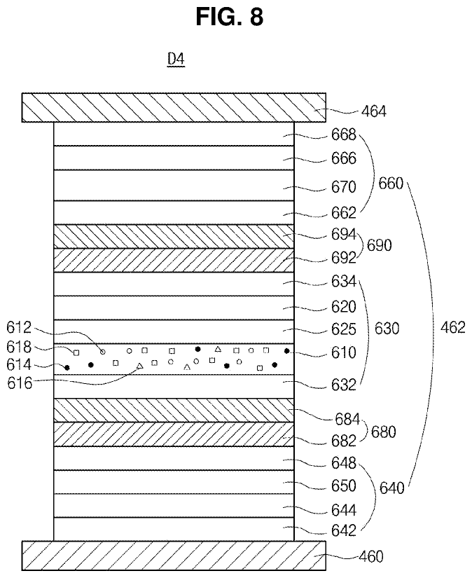

FIG. 8 is a cross-sectional view illustrating an OLED according to a sixth embodiment of the present disclosure.

As shown in FIG. 8, in the OLED D4, the organic emitting layer 462 includes a first emitting part 630 including a red EML 610 and green EML 620 and a yellow-green EML 625, a second emitting part 640 including a first blue EML 650 and a third emitting part 660 including a second blue EML 670. In addition, the organic emitting layer 462 may further include a first CGL 680 between the first and second emitting parts 630 and 640 and a second CGL 690 between the first and third emitting part 630 and 660.

The organic light emitting display device 400 includes red, green, and blue pixel regions, and the OLED D4 may be positioned in the red, green, and blue pixel regions.

The first electrode 460 is an anode, and the second electrode 464 is a cathode. One of the first and second electrodes 460 and 464 is a reflective electrode, and the other one of the first and second electrodes 460 and 464 is a transparent (semi-transparent) electrode.

For example, the first electrode 460 may include a transparent conductive material layer formed of ITO or IZO, and the second electrode 464 may include one of Al, Mg, Ag, AlMg, and MgAg.

The second emitting part 640 is positioned between the first electrode 460 and the first emitting part 630, and the third emitting part 660 is positioned between the first emitting part 630 and the second electrode 464. In addition, the second emitting part 640 is positioned between the first electrode 460 and the first CGL 680, and the third emitting part 660 is positioned between the second CGL 690 and the second electrode 464. Namely, the second emitting part 640, the first CGL 680, the first emitting part 630, the second CGL 690 and the third emitting part 660 are sequentially stacked on the first electrode 460.

In the first emitting part 630, the yellow-green EML 625 is positioned between the red EML 610 and the green EML 620. Namely, the red EML 610, the yellow-green EML 625 and the green EML 620 are sequentially stacked so that the first emitting part 630 includes an EML having a triple-layered structure.

The red EML 610 includes a first delayed fluorescent compound 612 represented by Formula 1, a second delayed fluorescent compound 614 represented by Formula 3, a first fluorescent compound 616 represented by Formula 5. The red EML 610 may further include a first host 618. The first delayed fluorescent compound 612 may be one of the compounds in Formula 2, and the second delayed fluorescent compound 614 may be one of the compounds in Formula 4. The first fluorescent compound 616 may be one of the compounds in Formula 6, and the first host 618 may be one of the compounds in Formula 7.

When the red EML 610 includes the first delayed fluorescent compound 612 represented by Formula 1 and the second delayed fluorescent compound 614 represented by Formula 3, an energy transfer efficiency to the first fluorescent compound 616 is improved. Accordingly, in the OLED D4 including the red EML 610 and the organic light emitting display device 400 including the OLED D4, the driving voltage is decreased, and the emitting efficiency and the lifespan are increased.

The red EML 610 may have a thickness of 5 to 80 nm, preferably 10 to 50 nm.

In the red EML 610, a weight % of each of the first delayed fluorescent compound 612 and the second delayed fluorescent compound 614 is greater than a weight % of the first fluorescent compound 616. The weight % of the first delayed fluorescent compound 612 and the weight % of the second delayed fluorescent compound 614 may be same or different.

In the red EML 610, each of the first and second delayed fluorescent compounds 612 and 614 may have a weight % of 5 to 50, the first fluorescent compound 616 may have a weight % of 0.1 to 5, and the first host 618 may have a weight % of 25 to 80.

In an aspect of the present disclosure, a weight % of the first host 618 may be greater than the weight % of each of the first delayed fluorescent compound 612 and the second delayed fluorescent compound 614. Namely, the weight % of each of the first delayed fluorescent compound 612 and the second delayed fluorescent compound 614 may be smaller than that of the first host 618 and may be greater than that of the first fluorescent compound 616.

For example, the first host 618 may have a weight % of 60 to 80, each of the first and second delayed fluorescent compounds 612 and 614 may have a weight % of 5 to 30, and the first fluorescent compound 616 may have a weight % of 0.1 to 5.

In an aspect of the present disclosure, a weight % of the first delayed fluorescent compounds 612 may be equal to or smaller than that of the second delayed fluorescent compounds 614.

The first delayed fluorescent compound 612 has a first LUMO energy level, and the second delayed fluorescent compound 614 has a second LUMO energy level lower than the first LUMO energy level. A difference “ΔLUMO1” between the first LUMO energy level and the second LUMO energy level may be 0.4 eV or less. (ΔLUMO1≤0.4 eV)

The first delayed fluorescent compound 612 has a first HOMO energy level, and the second delayed fluorescent compound 614 has a second HOMO energy level lower than the first HOMO energy level. A difference “ΔHOMO” between the first HOMO energy level and the second HOMO energy level may be 0.2 eV or less. (ΔHOMO≤0.2 eV)

The difference “ΔLUMO1” between the first LUMO energy level and the second LUMO energy level may be greater than the difference “ΔHOMO” between the first HOMO energy level and the second HOMO energy level. (ΔLUMO1>ΔHOMO)

The first fluorescent compound 616 has a third LUMO energy level higher than the second LUMO energy level. A difference “ΔLUMO2” between the second LUMO energy level and the third LUMO energy level may be 0.6 eV or less. (ΔLUMO2≤0.6 eV)

The difference “ΔLUMO2” between the second LUMO energy level and the third LUMO energy level may be greater than the difference “ΔLUMO1” between the first LUMO energy level and the second LUMO energy level. (ΔLUMO2>ΔLUMO1)

An energy bandgap (Eg) of each of the first delayed fluorescent compound 612 and the second delayed fluorescent compound 614 may be in a range of 2.0 to 3.0 eV. (2.0≤Eg≤3.0)

The green EML 620 includes a green host and a green dopant. The green EML 620 may have a thickness of 5 to 80 nm, preferably 10 to 50 nm.

The green host may be selected from the above-mentioned green host material, and the green dopant may be selected from the above-mentioned green dopant material.

The yellow-green EML 625 includes a yellow-green host and a yellow-green dopant. The yellow-green EML 625 may have a thickness of 5 to 80 nm, preferably 10 to 50 nm.

The yellow-green host may be same as the green host.

For example, the green dopant may be one of 5,6,11,12-tetraphenylnaphthalene (Rubrene), 2,8-di-tert-butyl-5,11-bis(4-tert-butylphenyl)-6,12-diphenyltetracene (TBRb), bis(2-phenylbenzothiazolato)(acetylacetonate)irdium(III) (Ir(BT)₂(acac)), bis(2-(9,9-diethytl-fluoren-2-yl)-1-phenyl-1H-benzo[d]imdiazolato)(acetylacetonate)iridium(III) (Ir(fbi)₂(acac)), bis(2-phenylpyridine)(3-(pyridine-2-yl)-2H-chromen-2-onate)iridium(III) (fac-Ir(ppy)₂Pc), bis(2-(2,4-difluorophenyl)quinoline)(picolinate)iridium(III) (FPQIrpic), and bis(4-phenylthieno[3,2-c]pyridinato-N,C2′) (acetylacetonate) iridium(III) (PO-01).

The first emitting part 630 may further include at least one of a first HTL 632 under the red EML 610 and a first ETL 634 over the red EML 610. When the first emitting part 630 includes the green EML 620, the first ETL 634 is positioned on the green EML 620.

The first emitting part 630 may further include at least one of a first EBL between the red EML 610 and the first HTL 632 and a first HBL between the green EML 620 and the first ETL 634.

The second emitting part 640 may further include at least one of a second HTL 644 under the first blue EML 650 and a second ETL 648 over the first blue EML 650. In addition, the second emitting part 640 may further include an HIL 642 between the first electrode 460 and the first HTL 644.

The second emitting part 640 may further include at least one of a second EBL between the second HTL 644 and the first blue EML 650 and a second HBL between the first blue EML 650 and the second ETL 648.

The third emitting part 660 may further include at least one of a third HTL 662 under the second blue EML 670 and a third ETL 666 over the second blue EML 670. In addition, the third emitting part 660 may further include an EIL 668 between the second electrode 464 and the third ETL 666.

The third emitting part 660 may further include at least one of a third EBL between the third HTL 662 and the second blue EML 670 and a third HBL between the second blue EML 670 and the third ETL 666.

The first blue EML 650 in the second emitting part 640 includes a first blue host and a first blue dopant, and the second blue EML 670 in the third emitting part 660 includes a second blue host and a second blue dopant.

The HIL 642 may include the above-mentioned hole injection material and may have a thickness of 1 to 20 nm, preferably 5 to 15 nm. Each of the first to third HTLs 632, 644, and 664 may include the above-mentioned hole transporting material and may have a thickness of 30 to 150 nm, preferably 50 to 100 nm.

Each of the first to third ETLs 634, 648, and 666 may include the above-mentioned electron transporting material and may have a thickness of 10 to 50 nm, preferably 20 to 40 nm. The EIL 668 may include the above-mentioned electron injection material and may have a thickness of 0.1 to 10 nm, preferably 0.5 to 5 nm.

Each of the first to third EBLs may include the above-mentioned electron blocking material and may have a thickness of 5 to 30 nm, preferably 10 to 20 nm. Each of the first to third HBLs may include the above-mentioned hole blocking material and may have a thickness of 1 to 20 nm, preferably 5 to 15 nm.

The first CGL 680 is positioned between the first and second emitting parts 630 and 640, and the second CGL 690 is positioned between the first and third emitting parts 630 and 660. Namely, the first and second emitting parts 630 and 640 is connected to each other by the first CGL 680, and the first and third emitting parts 630 and 660 is connected to each other by the second CGL 690. The first CGL 680 may be a P-N junction type CGL of an N-type CGL 682 and a P-type CGL 684, and the second CGL 690 may be a P-N junction type CGL of an N-type CGL 692 and a P-type CGL 694.

In the first CGL 680, the N-type CGL 682 is positioned between the first HTL 632 and the second ETL 648, and the P-type CGL 684 is positioned between the N-type CGL 682 and the first HTL 632.

In the second CGL 690, the N-type CGL 692 is positioned between the first ETL 634 and the third HTL 662, and the P-type CGL 694 is positioned between the N-type CGL 692 and the third HTL 662.

Each of the N-type CGL 682 of the first CGL 680 and the N-type CGL 692 of the second CGL 690 may include the above-mentioned N-type charge generation material, and each of the P-type CGL 684 of the first CGL 680 and the P-type CGL 694 of the second CGL 690 may include the above-mentioned P-type charge generation material.

As illustrated above, the OLED D4 of the present disclosure includes the first emitting part 630 including the red EML 610, the yellow-green EML 625 and the green EML 620, the second emitting part 640 including the first blue EML 650 and the third emitting part 660 including the second blue EML 670. As a result, the OLED D4 emits the white light.

In addition, the red EML 610 includes the first delayed fluorescent compound 612, which is represented by Formula 1, the second delayed fluorescent compound 614, which is represented by Formula 3, and the first fluorescent compound 616, which is represented by Formula 5. As a result, the OLED D4 has advantages in the driving voltage, the emitting efficiency and the lifespan.

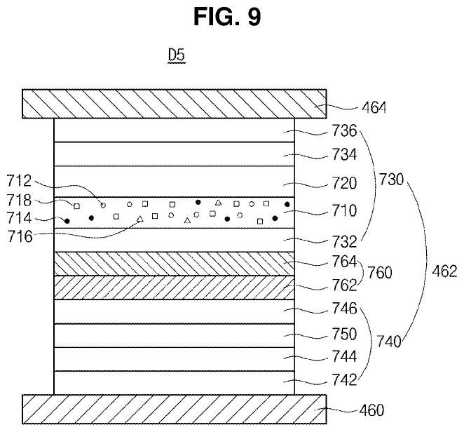

FIG. 9 is a cross-sectional view illustrating an OLED according to a seventh embodiment of the present disclosure.

As shown in FIG. 9, in the OLED D5, the organic emitting layer 462 includes a first emitting part 730 including a red EML 710 and a green EML 720 and a second emitting part 740 including a blue EML 750. In addition, the organic emitting layer 462 may further include a CGL 760 between the first and second emitting parts 730 and 740.

The organic light emitting display device 400 includes red, green, and blue pixel regions, and the OLED D5 may be positioned in the red, green and blue pixel regions.

The first electrode 460 is an anode, and the second electrode 464 is a cathode. One of the first and second electrodes 460 and 464 is a reflective electrode, and the other one of the first and second electrodes 460 and 464 is a transparent (semitransparent) electrode.

For example, the first electrode 460 may include a transparent conductive material layer formed of ITO or IZO, and the second electrode 464 may include one of Al, Mg, Ag, AlMg, and MgAg.

The first emitting part 730 is positioned between the CGL 760 and the second electrode 464, and the second emitting part 740 is positioned between the CGL 760 and the first electrode 460. Alternatively, the first emitting part 730 may be positioned between the CGL 760 and the first electrode 460, and the second emitting part 740 may be positioned between the CGL 760 and the second electrode 464.

In the first emitting part 730, the green EML 720 is positioned on the red EML 710.

The red EML 710 includes a first delayed fluorescent compound 712 represented by Formula 1, a second delayed fluorescent compound 714 represented by Formula 3, a first fluorescent compound 716 represented by Formula 5. The red EML 710 may further include a first host 718. The first delayed fluorescent compound 712 may be one of the compounds in Formula 2, and the second delayed fluorescent compound 714 may be one of the compounds in Formula 4. The first fluorescent compound 716 may be one of the compounds in Formula 6, and the first host 718 may be one of the compounds in Formula 7.

When the red EML 710 includes the first delayed fluorescent compound 712 represented by Formula 1 and the second delayed fluorescent compound 714 represented by Formula 3, an energy transfer efficiency to the first fluorescent compound 716 is improved. Accordingly, in the OLED D5 including the red EML 710 and the organic light emitting display device 400 including the OLED D5, the driving voltage is decreased, and the emitting efficiency and the lifespan are increased.

The red EML 710 may have a thickness of 5 to 80 nm, preferably 10 to 50 nm.

In the red EML 710, a weight % of each of the first delayed fluorescent compound 712 and the second delayed fluorescent compound 714 is greater than a weight % of the first fluorescent compound 716. The weight % of the first delayed fluorescent compound 712 and the weight % of the second delayed fluorescent compound 714 may be same or different.

In the red EML 710, each of the first and second delayed fluorescent compounds 712 and 714 may have a weight % of 5 to 50, the first fluorescent compound 716 may have a weight % of 0.1 to 5, and the first host 718 may have a weight % of 25 to 80.

In an aspect of the present disclosure, a weight % of the first host 718 may be greater than the weight % of each of the first delayed fluorescent compound 712 and the second delayed fluorescent compound 714. Namely, the weight % of each of the first delayed fluorescent compound 712 and the second delayed fluorescent compound 714 may be smaller than that of the first host 718 and may be greater than that of the first fluorescent compound 716.

For example, the first host 718 may have a weight % of 60 to 80, each of the first and second delayed fluorescent compounds 712 and 714 may have a weight % of 5 to 30, and the first fluorescent compound 716 may have a weight % of 0.1 to 5.

In an aspect of the present disclosure, a weight % of the first delayed fluorescent compounds 712 may be equal to or smaller than that of the second delayed fluorescent compounds 714.

The first delayed fluorescent compound 712 has a first LUMO energy level, and the second delayed fluorescent compound 714 has a second LUMO energy level lower than the first LUMO energy level. A difference “ΔLUMO1” between the first LUMO energy level and the second LUMO energy level may be 0.4 eV or less. (ΔLUMO1≤0.4 eV)

The first delayed fluorescent compound 712 has a first HOMO energy level, and the second delayed fluorescent compound 714 has a second HOMO energy level lower than the first HOMO energy level. A difference “A HOMO” between the first HOMO energy level and the second HOMO energy level may be 0.2 eV or less. (ΔHOMO≤0.2 eV)

The difference “ΔLUMO1” between the first LUMO energy level and the second LUMO energy level may be greater than the difference “ΔHOMO” between the first HOMO energy level and the second HOMO energy level. (ΔLUMO1>ΔHOMO)

The first fluorescent compound 716 has a third LUMO energy level higher than the second LUMO energy level. A difference “ΔLUMO2” between the second LUMO energy level and the third LUMO energy level may be 0.6 eV or less. (ΔLUMO2≤0.6 eV)

The difference “ΔLUMO2” between the second LUMO energy level and the third LUMO energy level may be greater than the difference “ΔLUMO1” between the first LUMO energy level and the second LUMO energy level. (ΔLUMO2>ΔLUMO1)

An energy bandgap (Eg) of each of the first delayed fluorescent compound 712 and the second delayed fluorescent compound 714 may be in a range of 2.0 to 3.0 eV. (2.0≤Eg≤3.0)

The green EML 720 includes a green host and a green dopant. The green EML 720 may have a thickness of 5 to 80 nm, preferably 10 to 50 nm.

The green host may be the above-mentioned green host material, and the green dopant may be the above-mentioned green dopant material.

The first emitting part 730 may further include at least one of a first HTL 732 under the red EML 710 and a first ETL 734 over the red EML 710. When the first emitting part 730 includes the green EML 720, the first ETL 734 is positioned on the green EML 720. In addition, the first emitting part 730 may further include an EIL 736 between the first ETL 734 and the second electrode 464.

The first emitting part 730 may further include at least one of a first EBL between the red EML 710 and the first HTL 732 and a first HBL between the green EML 720 and the first ETL 734.

The second emitting part 740 may further include at least one of a second HTL 744 under the first blue EML 750 and a second ETL 746 over the first blue EML 750. In addition, the second emitting part 740 may further include an HIL 742 between the first electrode 460 and the first HTL 744.

The second emitting part 740 may further include at least one of a second EBL between the second HTL 744 and the first blue EML 750 and a second HBL between the first blue EML 750 and the second ETL 746.

The blue EML 750 in the second emitting part 740 includes a blue host and a blue dopant.

The HIL 742 may include the above-mentioned hole injection material and may have a thickness of 1 to 20 nm, preferably 5 to 15 nm. Each of the first and second HTLs 732 and 744 may include the above-mentioned hole transporting material and may have a thickness of 30 to 150 nm, preferably 50 to 100 nm.

Each of the first and second ETLs 734 and 746 may include the above-mentioned electron transporting material and may have a thickness of 10 to 50 nm, preferably 20 to 40 nm. The EIL 736 may include the above-mentioned electron injection material and may have a thickness of 0.1 to 10 nm, preferably 0.5 to 5 nm.

Each of the first and second EBLs may include the above-mentioned electron blocking material and may have a thickness of 5 to 30 nm, preferably 10 to 20 nm. Each of the first and second HBLs may include the above-mentioned hole blocking material and may have a thickness of 1 to 20 nm, preferably 5 to 15 nm.

The CGL 760 is positioned between the first and second emitting parts 730 and 740. Namely, the first and second emitting parts 730 and 740 are connected to each other by the CGL 760. The CGL 760 may be a P-N junction type CGL of an N-type CGL 762 and a P-type CGL 764.

In the CGL 760, the N-type CGL 762 is positioned between the first HTL 732 and the second ETL 746, and the P-type CGL 764 is positioned between the N-type CGL 762 and the first HTL 732.

The N-type CGL 762 may include the above-mentioned N-type charge generation material, and the P-type CGL 764 may include the above-mentioned P-type charge generation material.

As illustrated above, the OLED D5 of the present disclosure includes the first emitting part 730 including the red EML 710 and the green EML 720 and the second emitting part 740 including the blue EML 750. As a result, the OLED D5 emits the white light.

In addition, the red EML 710 includes the first delayed fluorescent compound 712, which is represented by Formula 1, the second delayed fluorescent compound 714, which is represented by Formula 3, and the first fluorescent compound 716, which is represented by Formula 5. As a result, the OLED D5 has advantages in the driving voltage, the emitting efficiency and the lifespan.

### [OLED]

On an anode (ITO, 50 nm), an HIL (the compound in Formula 8, 7 nm), an HTL (the compound in Formula 9, 78 nm), an EBL (the compound in Formula 10, 15 nm, an EML (35 nm), an HBL (the compound in Formula 11, 10 nm), an ETL (the compound in Formula 12, 25 nm), an EIL (LiF, 1 nm), and a cathode (Al, 100 nm) were sequentially stacked to form an OLED.

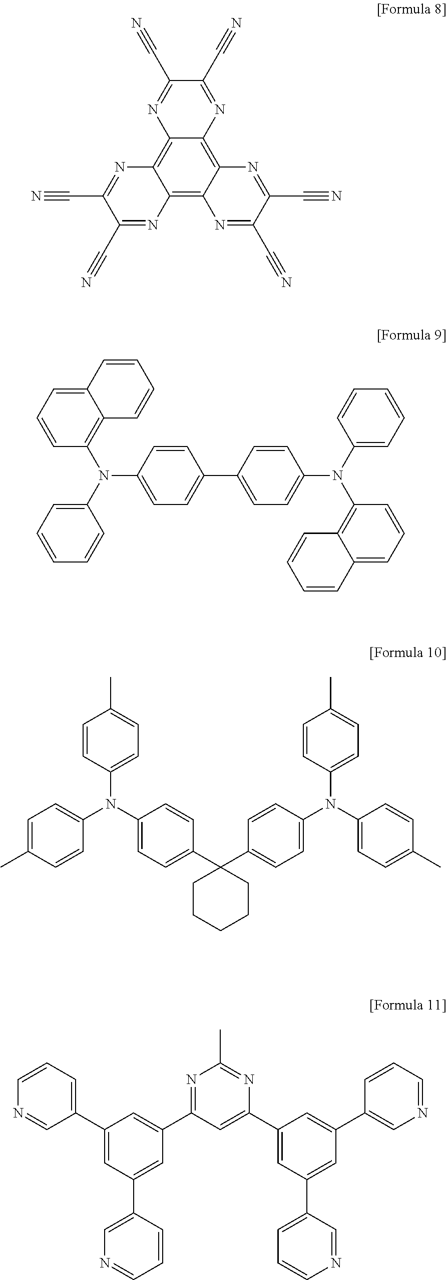

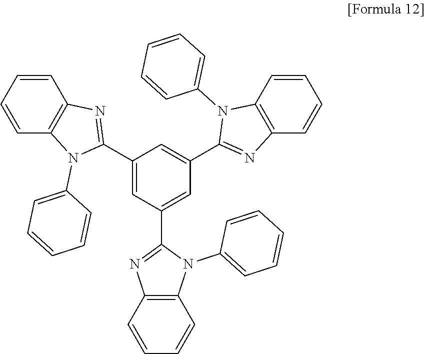 [SMILES: c1ccc(-n2c(-c3cc(-c4nc5ccccc5n4-c4ccccc4)cc(-c4nc5ccccc5n4-c4ccccc4)c3)nc3ccccc32)cc1]

### 1. Comparative Examples

### (1) Comparative Example 1 (Ref1)

The compound H1 (69.7 wt %) in Formula 7, the compound TD2-1 (29.8 wt %) in Formula 4 and the compound FD1 (0.5 wt %) in Formula 6 were used to form the EML.

### (2) Comparative Example 2 (Ref2)

The compound H1 (59.7 wt %) in Formula 7, the compound TD2-1 (39.8 wt %) in Formula 4 and the compound FD1 (0.5 wt %) in Formula 6 were used to form the EML.

### (3) Comparative Example 3 (Ref3)

The compound H1 (49.7 wt %) in Formula 7, the compound TD2-1 (49.8 wt %) in Formula 4 and the compound FD1 (0.5 wt %) in Formula 6 were used to form the EML.

### (4) Comparative Example 4 (Ref4)

The compound H1 (69 wt %) in Formula 7, the compound TD3 (30 wt %) in Formula 13 and the compound Ref_FD1 (1 wt %) in Formula 14 were used to form the EML.

### (5) Comparative Example 5 (Ref5)

The compound H1 (49 wt %) in Formula 7, the compound TD3 (50 wt %) in Formula 13 and the compound Ref_FD1 (1 wt %) in Formula 14 were used to form the EML.

### (6) Comparative Example 6 (Ref6)

The compound H1 (29 wt %) in Formula 7, the compound TD3 (70 wt %) in Formula 13 and the compound Ref_FD1 (1 wt %) in Formula 14 were used to form the EML.

### (7) Comparative Example 7 (Ref7)

The compound H1 (49.8 wt %) in Formula 7, the compound TD4 (32.8 wt %) in Formula 13, the compound TD3 (16.9 wt %) in Formula 13 and the compound FD1 (0.5 wt %) in Formula 6 were used to form the EML.

### (8) Comparative Example 8 (Ref8)

The compound H1 (49.7 wt %) in Formula 7, the compound TD4 (24.9 wt %) in Formula 13, the compound TD3 (24.9 wt %) in Formula 13 and the compound FD1 (0.5 wt %) in Formula 6 were used to form the EML.

### (9) Comparative Example 9 (Ref9)

The compound H1 (49.8 wt %) in Formula 7, the compound TD4 (16.9 wt %) in Formula 13, the compound TD3 (32.8 wt %) in Formula 13 and the compound FD1 (0.5 wt %) in Formula 6 were used to form the EML.

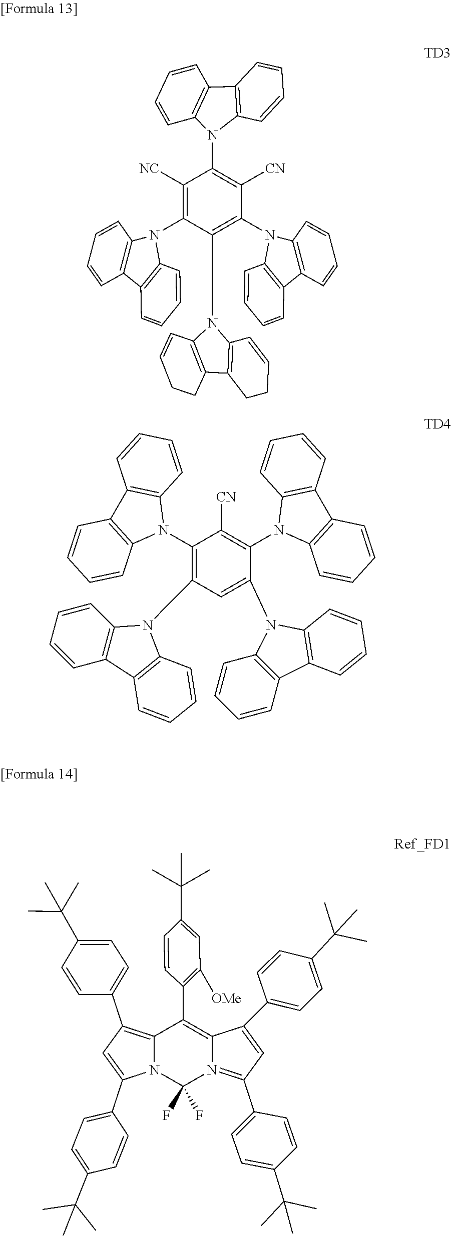

### 2. Examples

### (1) Example 1 (Ex1)

The compound H1 (29.8 wt %) in Formula 7, the compound TD1-1 (46.8 wt %) in Formula 2, the compound TD2-1 (22.9 wt %) in Formula 4 and the compound FD1 (0.5 wt %) in Formula 6 were used to form the EML.

### (2) Example 2 (Ex2)

The compound H1 (29.9 wt %) in Formula 7, the compound TD1-1 (34.8 wt %) in Formula 2, the compound TD2-1 (34.8 wt %) in Formula 4 and the compound FD1 (0.5 wt %) in Formula 6 were used to form the EML.

### (3) Example 3 (Ex3)

The compound H1 (29.8 wt %) in Formula 7, the compound TD1-1 (22.9 wt %) in Formula 2, the compound TD2-1 (46.8 wt %) in Formula 4 and the compound FD1 (0.5 wt %) in Formula 6 were used to form the EML.

### (4) Example 4 (Ex4)

The compound H1 (49.8 wt %) in Formula 7, the compound TD1-1 (32.8 wt %) in Formula 2, the compound TD2-1 (16.9 wt %) in Formula 4 and the compound FD1 (0.5 wt %) in Formula 6 were used to form the EML.

### (5) Example 5 (Ex5)

The compound H1 (49.7 wt %) in Formula 7, the compound TD1-1 (24.9 wt %) in Formula 2, the compound TD2-1 (24.9 wt %) in Formula 4 and the compound FD1 (0.5 wt %) in Formula 6 were used to form the EML.

### (6) Example 6 (Ex6)

The compound H1 (49.8 wt %) in Formula 7, the compound TD1-1 (16.9 wt %) in Formula 2, the compound TD2-1 (32.8 wt %) in Formula 4 and the compound FD1 (0.5 wt %) in Formula 6 were used to form the EML.

### (7) Example 7 (Ex7)

The compound H1 (69.6 wt %) in Formula 7, the compound TD1-1 (19.9 wt %) in Formula 2, the compound TD2-1 (10 wt %) in Formula 4 and the compound FD1 (0.5 wt %) in Formula 6 were used to form the EML.

### (8) Example 8 (Ex8)

The compound H1 (69.7 wt %) in Formula 7, the compound TD1-1 (14.9 wt %) in Formula 2, the compound TD2-1 (14.9 wt %) in Formula 4 and the compound FD1 (0.5 wt %) in Formula 6 were used to form the EML.

### (9) Example 9 (Ex9)

The compound H1 (69.6 wt %) in Formula 7, the compound TD1-1 (10 wt %) in Formula 2, the compound TD2-1 (19.9 wt %) in Formula 4 and the compound FD1 (0.5 wt %) in Formula 6 were used to form the EML.

The HOMO energy level and the LUMO energy level of the delayed fluorescent compounds and the fluorescent compounds used in the OLED of Comparative Examples 1 to 9 and Examples 1 to 9 were measured and listed in Tables 1 and 2.

Various methods of determining the HOMO energy level are known to the skilled person. For example, the HOMO energy level can be determined using a conventional surface analyser such as an AC3 surface analyser made by RKI instruments. The surface analyser may be used to interrogate a single film (neat film) of a compound with a thickness of 50 nm. The LUMO energy level can be calculated as follows:

$$LUMO = HOMO ‐ bandgap .$$

The bandgap may be calculated using any conventional method known to the skilled person, such as from a UV-vis measurement of a single film with a thickness of 50 nm. For example, this can be done using a SCINCO S-3100 spectrophotometer. The HOMO and LUMO values of the compounds of the examples and embodiments disclosed herein may be determined in this way. Namely, the HOMO and LUMO values may be experimentally or empirically determined values of thin films, such as 50 nm films.

TABLE 1

| | | TD1 | | TD2 | | FD | |
|---|---|---|---|---|---|---|---|
| | | | HOMO/ | | HOMO/ | | HOMO/ |
| | host | | LUMO | | LUMO | | LUMO |
| Ref1 | H1 | — | — | TD2-1 | −5.9/−3.4 | FD1 | −4.8/−2.9 |
| Ref2 | H1 | — | — | TD2-1 | −5.9/−3.4 | FD1 | −4.8/−2.9 |
| Ref3 | H1 | — | — | TD2-1 | −5.9/−3.4 | FD1 | −4.8/−2.9 |
| Ref4 | H1 | TD3 | −5.8/−3.4 | — | — | Ref_FD1 | −5.5/3.5 |
| Ref5 | H1 | TD3 | −5.8/−3.4 | — | — | Ref_FD1 | −5.5/3.5 |
| Ref6 | H1 | TD3 | −5.8/−3.4 | — | — | Ref_FD1 | −5.5/3.5 |
| Ref7 | H1 | TD4 | −5.9/−3.0 | TD3 | −5.8/−3.4 | FD1 | −4.8/−2.9 |
| Ref8 | H1 | TD4 | −5.9/−3.0 | TD3 | −5.8/−3.4 | FD1 | −4.8/−2.9 |
| Ref9 | H1 | TD4 | −5.9/−3.0 | TD3 | −5.8/−3.4 | FD1 | −4.8/−2.9 |

TABLE 2

| | | TD1 | | TD2 | | FD | |
|---|---|---|---|---|---|---|---|
| | | | HOMO/ | | HOMO/ | | HOMO/ |
| | host | | LUMO | | LUMO | | LUMO |
| Ex1 | H1 | TD1-1 | −5.8/−3.0 | TD2-1 | −5.9/−3.4 | FD1 | −4.8/−2.9 |
| Ex2 | H1 | TD1-1 | −5.8/−3.0 | TD2-1 | −5.9/−3.4 | FD1 | −4.8/−2.9 |
| Ex3 | H1 | TD1-1 | −5.8/−3.0 | TD2-1 | −5.9/−3.4 | FD1 | −4.8/−2.9 |
| Ex4 | H1 | TD1-1 | −5.8/−3.0 | TD2-1 | −5.9/−3.4 | FD1 | −4.8/−2.9 |
| Ex5 | H1 | TD1-1 | −5.8/−3.0 | TD2-1 | −5.9/−3.4 | FD1 | −4.8/−2.9 |
| Ex6 | H1 | TD1-1 | −5.8/−3.0 | TD2-1 | −5.9/−3.4 | FD1 | −4.8/−2.9 |
| Ex7 | H1 | TD1-1 | −5.8/−3.0 | TD2-1 | −5.9/−3.4 | FD1 | −4.8/−2.9 |
| Ex8 | H1 | TD1-1 | −5.8/−3.0 | TD2-1 | −5.9/−3.4 | FD1 | −4.8/−2.9 |
| Ex9 | H1 | TD1-1 | −5.8/−3.0 | TD2-1 | −5.9/−3.4 | FD1 | −4.8/−2.9 |

The properties, i.e., a driving voltage (V, [V]), a maximum emission peak (λmax, [nm]), an external quantum efficiency (EQE, [%]) and a lifespan (LT95, [%]), of the OLEDs manufactured in Comparative Examples 1 to 9 and Examples 1 to 9 were measured and listed in Tables 3 to 4.

TABLE 3

| | V | λmax | EQE | LT95 |
|---|---|---|---|---|
| Ref1 | 4.77 | 622 | 15.1 | 82 |
| Ref2 | 4.92 | 622 | 15.4 | 84 |
| Ref3 | 4.94 | 622 | 16.6 | 100 |
| Ref4 | 4.12 | 622 | 13.5 | 6 |
| Ref5 | 4.26 | 622 | 13.3 | 20 |
| Ref6 | 4.40 | 622 | 13.1 | 50 |
| Ref7 | 3.53 | 624 | 13.3 | 79 |
| Ref8 | 3.49 | 624 | 13.6 | 83 |
| Ref9 | 3.66 | 624 | 14.3 | 82 |

TABLE 4

| | V | λmax | EQE | LT95 |
|---|---|---|---|---|
| Ex1 | 3.47 | 624 | 15.5 | 91 |
| Ex2 | 3.49 | 624 | 15.9 | 94 |
| Ex3 | 3.49 | 624 | 15.4 | 98 |
| Ex4 | 3.34 | 624 | 14.9 | 98 |
| Ex5 | 3.37 | 624 | 15.0 | 99 |
| Ex6 | 3.40 | 624 | 15.6 | 103 |
| Ex7 | 3.28 | 624 | 14.8 | 93 |
| Ex8 | 3.33 | 624 | 14.8 | 101 |
| Ex9 | 3.32 | 624 | 14.9 | 100 |

As shown in Tables 3 and 4, in comparison to the OLED of Comparative Examples 1 to 9, the OLED of Examples 1 to 9 has an advantage in at least one of the driving voltage, the emitting efficiency and the lifespan.

For example, in comparison to the OLED of Comparative Examples 1 to 3, the driving voltage of the OLED of Examples 1 to 9 is significantly decreased.

In addition, in comparison to the OLED of Comparative Examples 4 to 6, in the OLED of Examples 1 to 9, the driving voltage is significantly decreased, and the emitting efficiency and the lifespan are significantly increased.

Moreover, in comparison to the OLED of Comparative Examples 7 to 9, the emitting efficiency and the lifespan of the OLED of Examples 1 to 9 are significantly decreased.

Furthermore, in comparison to the OLED of Examples 1, 4, and 7, in the OLED of Examples 2, 3, 5, 6, 8 and 9, at least one of the emitting efficiency and the lifespan is improved. Namely, when a weight % of the first delayed fluorescent compound is equal to or smaller than that of the second delayed fluorescent compound, at least one of the emitting efficiency and the lifespan of the OLED is improved.

In comparison to the OLED of Examples 1 to 3, in the OLED of Examples 4 to 9, at least one of the driving voltage, the emitting efficiency and the lifespan is improved. Namely, when a weight % of the host is greater than that of each of the first and second delayed fluorescent compounds, at least one of the driving voltage, the emitting efficiency and the lifespan of the OLED is improved.

It will be apparent to those skilled in the art that various modifications and variations can be made in the embodiments of the present disclosure without departing from the spirit or scope of the present disclosure. Thus, it is intended that the present disclosure cover the modifications and variations provided they come within the scope of the appended claims and their equivalents.

What is claimed is:

1. An organic light emitting diode, comprising:
a first electrode;
a second electrode facing the first electrode; and
a first emitting part including a first red emitting material layer and positioned between the first electrode and the second electrode, the first red emitting material layer including a first delayed fluorescent compound, a second delayed fluorescent compound, and a first fluorescent compound,
wherein the first delayed fluorescent compound is represented by Formula 1: 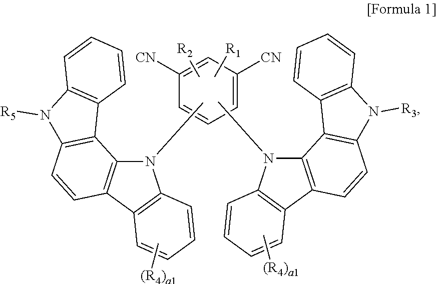
wherein in the Formula 1,
each of a1 and a2 is independently an integer of 0 to 4,
each of R₁ and R₂ is independently selected from the group consisting of a substituted or unsubstituted C6 to C30 aryl group and a substituted or unsubstituted C3 to C30 heteroaryl group,
each of R₃ and R₅ is independently selected from the group consisting of hydrogen, deuterium, a substituted or unsubstituted C1 to C10 alkyl group, a substituted or unsubstituted C6 to C30 aryl group and a substituted or unsubstituted C3 to C30 heteroaryl group, and
each of R₄ and R₆ is independently selected from the group consisting of a substituted or unsubstituted C1 to C10 alkyl group, a substituted or unsubstituted C1 to C10 alkoxy group, a substituted or unsubstituted C3 to C30 cycloalkyl group, a substituted or unsubstituted C6 to C30 aryl group and a substituted or unsubstituted C3 to C30 heteroaryl group,
wherein the second delayed fluorescent compound is represented by Formula 3: 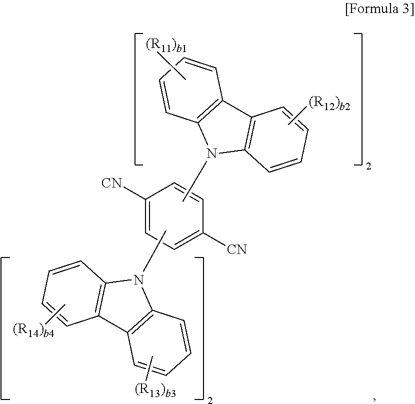
wherein in the Formula 3,
each of b1 to b4 is independently an integer of 0 to 4, and
each of R₁₁ to R₁₄ is independently selected from the group consisting of a substituted or unsubstituted C1 to C10 alkyl group, a substituted or unsubstituted C1 to C10 alkoxy group, a substituted or unsubstituted C3 to C30 cycloalkyl group, a substituted or unsubstituted C6 to C30 aryl group and a substituted or unsubstituted C3 to C30 heteroaryl group,
wherein the first fluorescent compound is represented by Formula 5: 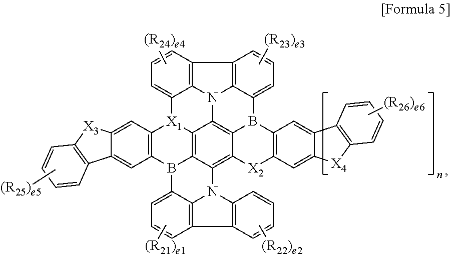
wherein in the Formula 5,
each of e1 and e3 is independently an integer of 0 to 3, each of e2, e4, e5 and e6 is independently an integer of 0 to 4, and n is 0 or 1,
each of X₁, X₂, X₃ and X₄ is independently selected from the group consisting of O, S, Se and Te, and
each of R₂₁ to R₂₆ is independently selected from the group consisting of deuterium, a substituted or unsubstituted C1 to C10 alkyl group, a substituted or unsubstituted C1 to C10 alkoxy group, a substituted or unsubstituted C3 to C30 cycloalkyl group, a substituted or unsubstituted C6 to C30 aryl group and a substituted or unsubstituted C3 to C30 heteroaryl group.

2. The organic light emitting diode according to claim 1, wherein the Formula 1 is represented by Formula 1a: 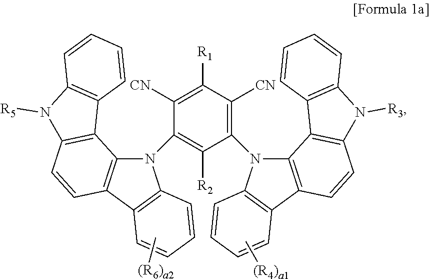
wherein in the Formula 1a, definitions of R₁ to R₆, a1 and a2 are same as those in Formula 1.

3. The organic light emitting diode according to claim 1, wherein the first delayed fluorescent compound is one of compounds in Formula 2:

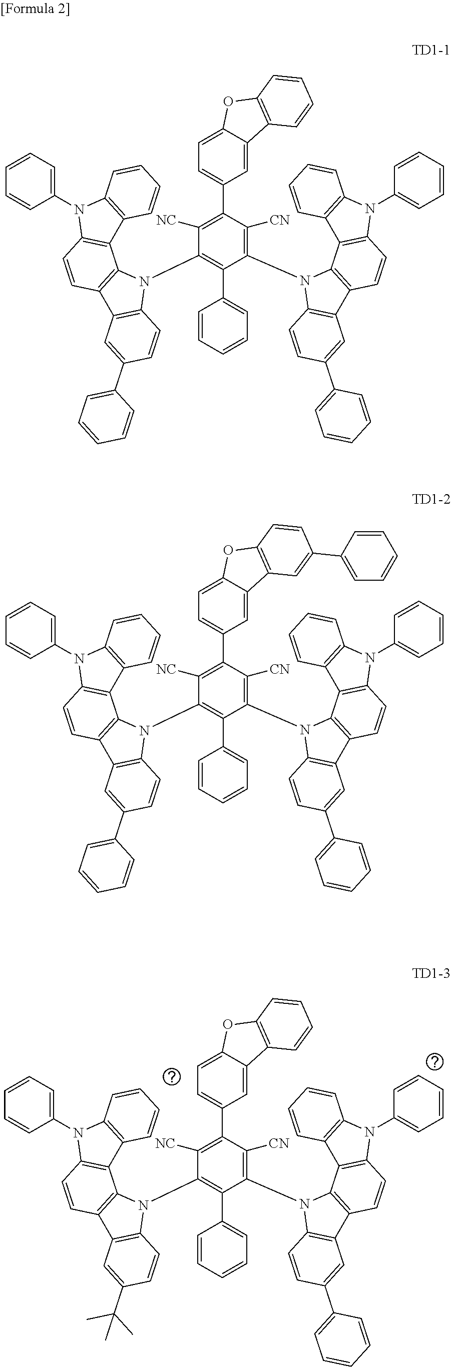 [SMILES: N#Cc1c(-c2ccc3oc4ccccc4c3c2)c(C#N)c(-n2c3ccc(-c4ccccc4)cc3c3ccc4c(c5ccccc5n4-c4ccccc4)c32)c(-c2ccccc2)c1-n1c2ccc(-c3ccccc3)cc2c2ccc3c(c4ccccc4n3-c3ccccc3)c21 ; N#Cc1c(-c2ccc3oc4ccc(-c5ccccc5)cc4c3c2)c(C#N)c(-n2c3ccc(-c4ccccc4)cc3c3ccc4c(c5ccccc5n4-c4ccccc4)c32)c(-c2ccccc2)c1-n1c2ccc(-c3ccccc3)cc2c2ccc3c(c4ccccc4n3-c3ccccc3)c21 ; CC(C)(C)c1ccc2c(c1)c1ccc3c(c4ccccc4n3-c3ccccc3)c1n2-c1c(C#N)c(-c2ccc3oc4ccccc4c3c2)c(C#N)c(-n2c3ccc(-c4ccccc4)cc3c3ccc4c(c5ccccc5n4-c4ccccc4)c32)c1-c1ccccc1]

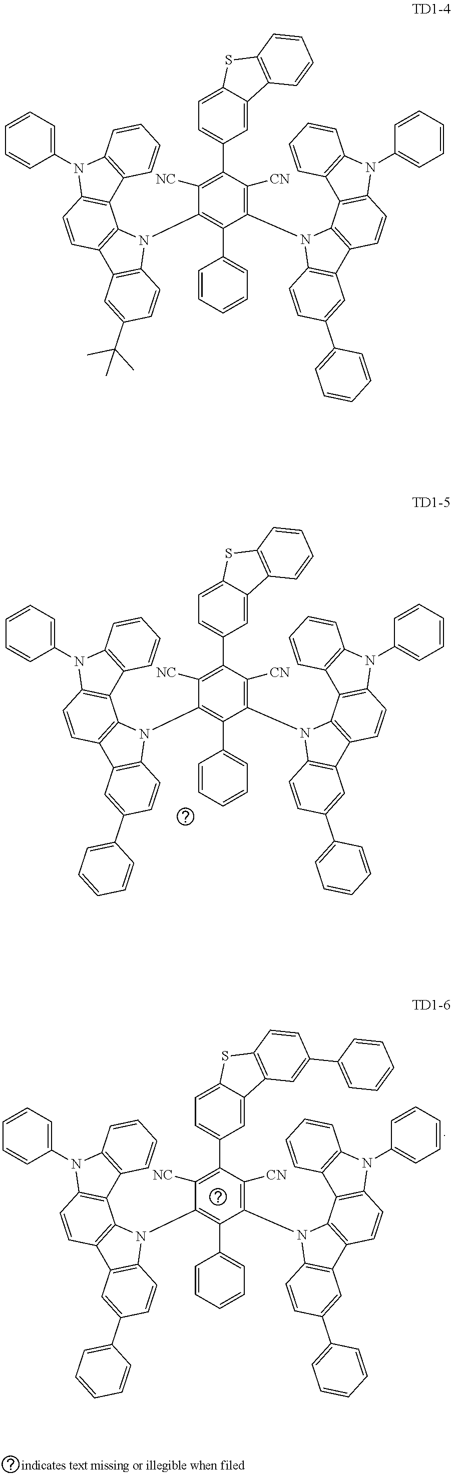 [SMILES: CC(C)(C)c1ccc2c(c1)c1ccc3c(c4ccccc4n3-c3ccccc3)c1n2-c1c(C#N)c(-c2ccc3sc4ccccc4c3c2)c(C#N)c(-n2c3ccc(-c4ccccc4)cc3c3ccc4c(c5ccccc5n4-c4ccccc4)c32)c1-c1ccccc1 ; N#Cc1c(-c2ccc3sc4ccccc4c3c2)c(C#N)c(-n2c3ccc(-c4ccccc4)cc3c3ccc4c(c5ccccc5n4-c4ccccc4)c32)c(-c2ccccc2)c1-n1c2ccc(-c3ccccc3)cc2c2ccc3c(c4ccccc4n3-c3ccccc3)c21 ; N#Cc1c(-c2ccc3sc4ccc(-c5ccccc5)cc4c3c2)c(C#N)c(-n2c3ccc(-c4ccccc4)cc3c3ccc4c(c5ccccc5n4-c4ccccc4)c32)c(-c2ccccc2)c1-n1c2ccc(-c3ccccc3)cc2c2ccc3c(c4ccccc4n3-c3ccccc3)c21]

4. The organic light emitting diode according to claim 1, wherein the Formula 3 is represented by Formula 3a: 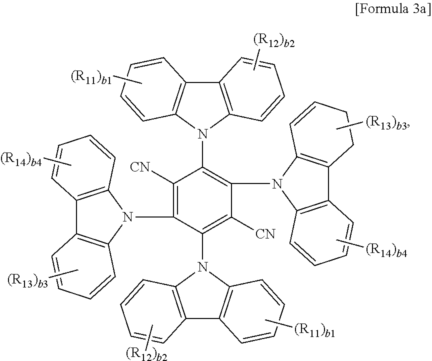
wherein in the Formula 3a, definitions of b1 to b4 and R₁₁ to R₁₄ are same as those in Formula 3.

5. The organic light emitting diode according to claim 1, wherein the second delayed fluorescent compound is one of compounds in Formula 4:

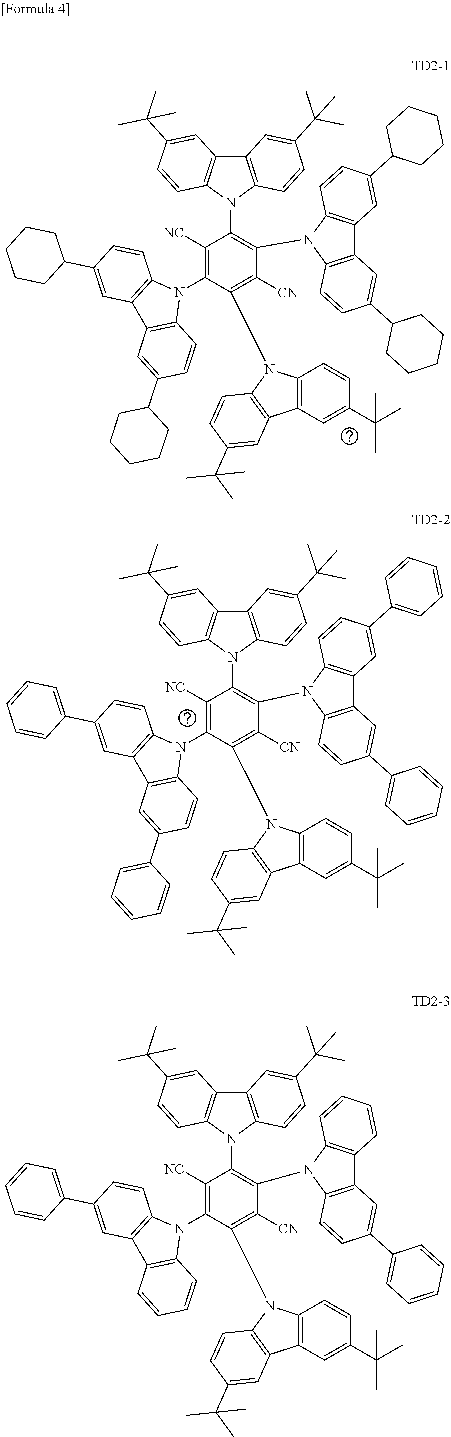

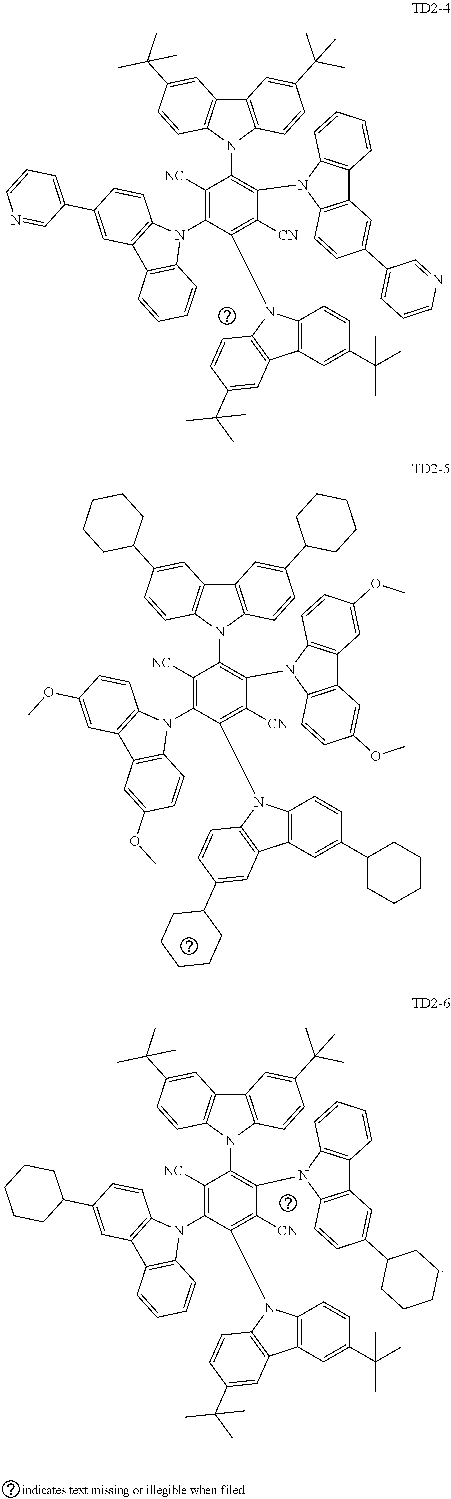 [SMILES: CC(C)(C)c1ccc2c(c1)c1cc(C(C)(C)C)ccc1n2-c1c(C#N)c(-n2c3ccccc3c3cc(-c4cccnc4)ccc32)c(-n2c3ccc(C(C)(C)C)cc3c3cc(C(C)(C)C)ccc32)c(C#N)c1-n1c2ccccc2c2cc(-c3cccnc3)ccc21 ; COc1ccc2c(c1)c1cc(OC)ccc1n2-c1c(C#N)c(-n2c3ccc(C4CCCCC4)cc3c3cc(C4CCCCC4)ccc32)c(-n2c3ccc(OC)cc3c3cc(OC)ccc32)c(C#N)c1-n1c2ccc(C3CCCCC3)cc2c2cc(C3CCCCC3)ccc21 ; CC(C)(C)c1ccc2c(c1)c1cc(C(C)(C)C)ccc1n2-c1c(C#N)c(-n2c3ccccc3c3cc(C4CCCCC4)ccc32)c(-n2c3ccc(C(C)(C)C)cc3c3cc(C(C)(C)C)ccc32)c(C#N)c1-n1c2ccccc2c2cc(C3CCCCC3)ccc21]

6. The organic light emitting diode according to claim 1, wherein the first fluorescent compound is one of compounds in Formula 6:

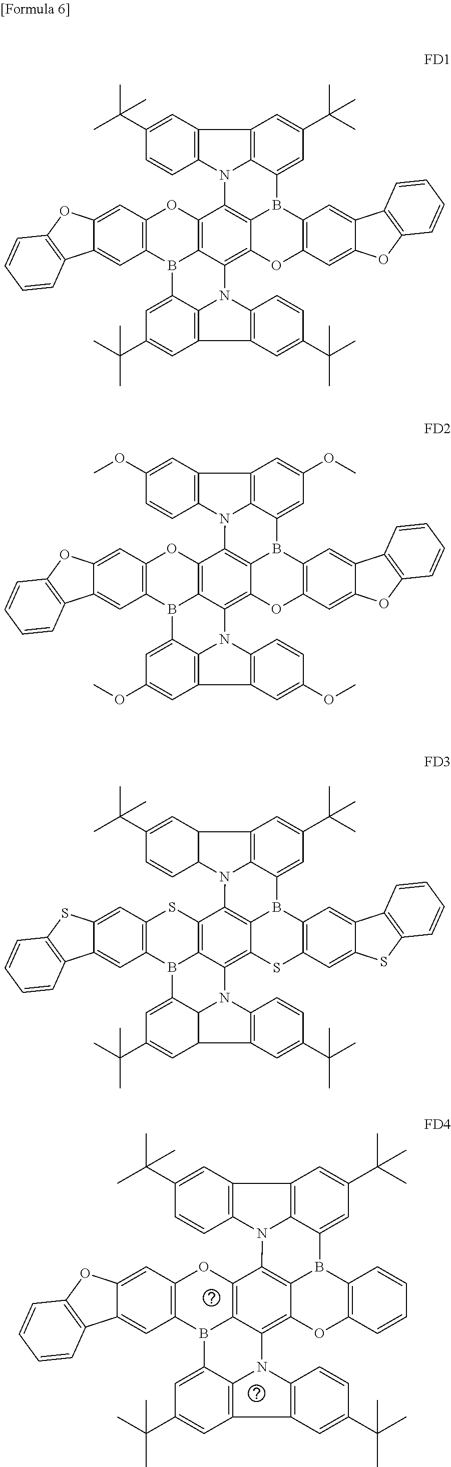

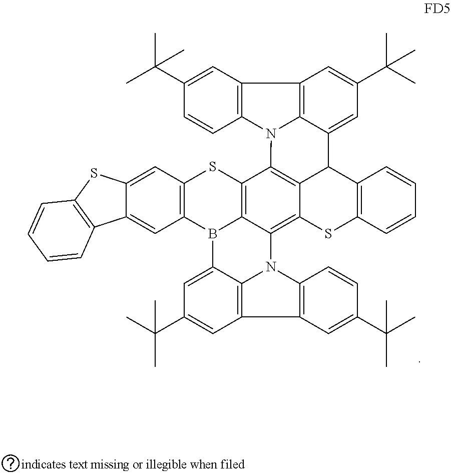 [SMILES: CC(C)(C)c1ccc2c(c1)c1cc(C(C)(C)C)cc3c1n2-c1c2c4c(c5c1B3c1cc3c(cc1S5)sc1ccccc13)-n1c3ccc(C(C)(C)C)cc3c3cc(C(C)(C)C)cc(c31)C4c1ccccc1S2]

7. The organic light emitting diode according to claim 1, wherein the first red emitting material layer further includes a host.

8. The organic light emitting diode according to claim 7, wherein the host is one of compounds in Formula 7:

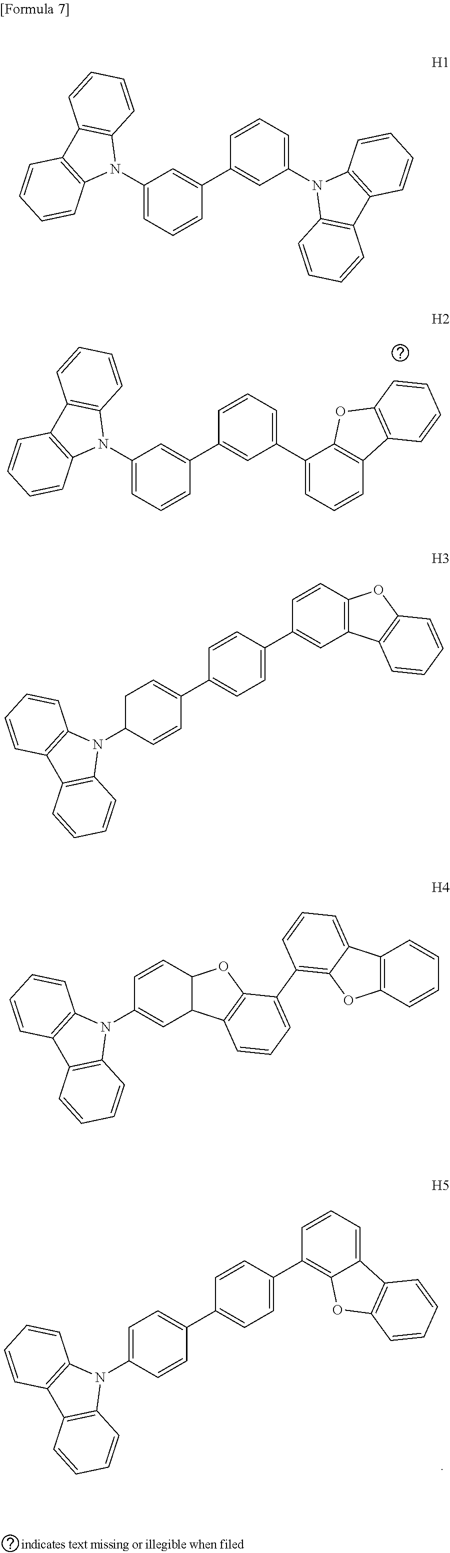 [SMILES: c1cc(-c2cccc(-n3c4ccccc4c4ccccc43)c2)cc(-n2c3ccccc3c3ccccc32)c1 ; c1cc(-c2cccc(-n3c4ccccc4c4ccccc43)c2)cc(-c2cccc3c2oc2ccccc23)c1 ; C1=CC(n2c3ccccc3c3ccccc32)CC=C1c1ccc(-c2ccc3oc4ccccc4c3c2)cc1 ; C1=CC2Oc3c(-c4cccc5c4oc4ccccc45)cccc3C2C=C1n1c2ccccc2c2ccccc21 ; c1ccc2c(c1)oc1c(-c3ccc(-c4ccc(-n5c6ccccc6c6ccccc65)cc4)cc3)cccc12]

9. The organic light emitting diode according to claim 7, wherein a weight % of each of the first delayed fluorescent compound and the second delayed fluorescent compound is smaller than a weight % of the host and greater than a weight % of the first fluorescent compound.

10. The organic light emitting diode according to claim 9, wherein the weight % of the first delayed fluorescent compound is equal to or smaller than the weight % of the second delayed fluorescent compound.

11. The organic light emitting diode according to claim 1, wherein a weight % of each of the first delayed fluorescent compound and the second delayed fluorescent compound is greater than a weight % of the first fluorescent compound.

12. The organic light emitting diode according to claim 11, wherein the weight % of the first delayed fluorescent compound is equal to or smaller than the weight % of the second delayed fluorescent compound.

13. The organic light emitting diode according to claim 1, further comprising:
a second emitting part including a second red emitting material layer and positioned between the first emitting part and the second electrode; and
a charge generation layer between the first emitting part and the second emitting part.

14. The organic light emitting diode according to claim 13, wherein the second red emitting material layer includes a third delayed fluorescent compound, a fourth delayed fluorescent compound, and a second fluorescent compound.

15. The organic light emitting diode according to claim 14, wherein the third delayed fluorescent compound is represented by the Formula 1, and the fourth delayed fluorescent compound is represented by the Formula 3, and
wherein the second fluorescent compound is represented by the Formula 5.

16. The organic light emitting diode according to claim 1, further comprising:
a second emitting part including a first blue emitting material layer and positioned between the first electrode and the first emitting part; and
a first charge generation layer between the first emitting part and the second emitting part.

17. The organic light emitting diode according to claim 16, further comprising:
a third emitting part including a second blue emitting material layer and positioned between the first emitting part and the second electrode; and
a second charge generation layer between the first emitting part and the third emitting part.

18. The organic light emitting diode according to claim 17, wherein the first emitting part further includes a green emitting material layer between the first red emitting material layer and the second charge generation layer.

19. The organic light emitting diode according to claim 18, wherein the first emitting part further includes a yellow-green emitting material layer between the red emitting material layer and the green emitting material layer.

20. An organic light emitting device, comprising:
a substrate;
the organic light emitting diode of claim 1 and disposed over the substrate; and
an encapsulation layer covering the organic light emitting diode.
